(19) United States
(12) Patent Application Publication
(10) Pub. No.: US 2015/0062824 A1
(43) Pub. Date: Mar. 5, 2015

(54) SEMICONDUCTOR DEVICE HAVING THERMOELECTRIC MODULE

(71) Applicant: Samsung Electronics Co., Ltd., Suwon-si (KR)

(72) Inventors: YOUNG-HOON HYUN, Seoul (KR); JI-CHUL KIM, Yongin-si (KR); YUN-HYEOK IM, Hwaseong-si (KR)

(21) Appl. No.: 14/302,239

(22) Filed: Jun. 11, 2014

(30) Foreign Application Priority Data
Sep. 4, 2013 (KR) 10-2013-0106199

(51) Int. Cl. H05K 7/20

(52) U.S. Cl. CPC H05K 7/20509
USPC 361/716

(57) ABSTRACT

A heat spreader is formed on a first semiconductor package and a second semiconductor package adjacent to the first semiconductor package, and first and second thermoelectric modules are included between the first and second semiconductor packages and the heat spreader. The first and second thermoelectric modules are formed to have opposite polarities, and the heat spreader heated by the first thermoelectric module is cooled due to activation of the second thermoelectric module.

### CROSS-REFERENCE TO RELATED APPLICATION

This application claims priority under 35 U.S.C. §119 to Korean Patent Application No. 10-2013-0106199 filed on Sep. 4, 2013, the disclosure of which is hereby incorporated by reference in its entirety.

### BACKGROUND

1. Field

Embodiments of the disclosed subject matter relate to a semiconductor device having a heat spreader.

2. Description of Related Art

With high integration, the number of micro semiconductor devices integrated into a single semiconductor chip is increased. The increase in the number of micro semiconductor devices causes increase in an amount of heat emitted in an operation of the semiconductor chip. A thermoelectric module may be used to reduce the heat generated into the semiconductor chip. However, in a cooling method using the thermoelectric module in the related art, heat pumped to a heat spreader from the thermoelectric module is accumulated in the heat spreader. There is a need for technology for preventing heat generated in the thermoelectric module from being accumulated in the heat spreader.

### SUMMARY

Embodiments of the disclosed subject matter provide a semiconductor device advantageous to high integration with improvement of heat emission characteristics.

Aspects of the disclosed subject matter should not be limited by the above description, and other unmentioned aspects will be clearly understood by one of ordinary skill in the art from example embodiments described herein.

In accordance with an aspect of the disclosed subject matter, a semiconductor device is provided. The semiconductor device may include a first semiconductor package, a second semiconductor package adjacent to the first semiconductor package, and a heat spreader formed on the first and second semiconductor packages. The semiconductor device may include a first thermoelectric module between the first semiconductor package and the heat spreader, and a second thermoelectric module between the second semiconductor package and the heat spreader. The semiconductor device may include a first temperature sensor between the first thermoelectric module and the first semiconductor package, and a second temperature sensor between the first thermoelectric module and the heat spreader. The first and second temperature sensors may be electrically connected to a controller.

In accordance with another aspect of the disclosed subject matter, a semiconductor device is provided. The semiconductor device may include a semiconductor chip having a low temperature region and a high temperature region, a heat spreader formed on the semiconductor chip, a first thermoelectric module having a heat absorption portion and a heat generation portion and disposed between the high temperature region of the semiconductor chip and the heat spreader, and a second thermoelectric module having a second heat absorption portion and a second heat generation portion and disposed between the low temperature region of the semiconductor chip and the heat spreader. The first heat absorption portion of the first thermoelectric module may be close to the high temperature region of the semiconductor chip. The first heat generation portion of the first thermoelectric module may be close to the heat spreader. The second heat absorption portion of the second thermoelectric module may be close to the heat spreader. The second heat generation portion of the second thermoelectric module may be close to the low temperature region of the semiconductor chip.

In accordance with yet another aspect of the disclosed subject matter, an apparatus may include a semiconductor device, a heat spreader, a plurality of thermoelectric modules, and a controller. The thermoelectric modules may be disposed between the semiconductor device and the heat spreader. Each of the thermoelectric modules may be configured to either absorb heat or generate heat in response to a respective applied voltage. The controller may be configured to apply a respective voltage to each of the thermoelectric modules in order to pump heat between the semiconductor device and the heat spreader.

Specific particulars of other embodiments are included in detailed descriptions and drawings.

### BRIEF DESCRIPTION OF THE DRAWINGS

The foregoing and other features and advantages of the disclosed subject matter will be apparent from the more particular description of preferred embodiments of the disclosed subject matter, as illustrated in the accompanying drawings in which like reference characters refer to the same parts throughout the different views. The drawings are not necessarily to scale, emphasis instead being placed upon illustrating the principles of the disclosed subject matter. In the drawings:

FIG. 1 is a cross-sectional view illustrating a configuration of a semiconductor device according to an embodiment of the disclosed subject matter;

FIGS. 2 and 3 are views explaining forward activation and reverse activation of a thermoelectric module according to a configuration of a semiconductor device of the disclosed subject matter;

FIG. 4 is a view illustrating an technique for controlling a semiconductor device according to an embodiment of the disclosed subject matter;

FIGS. 5, 6, and 7 are graphs illustrating control of heat generated in a semiconductor device using a thermoelectric module;

FIGS. 8, 9, 10, and 11 are plan views illustrating other configurations of a thermoelectric module in a semiconductor device according to an embodiment of the disclosed subject matter;

FIGS. 12, 13, and 14 are cross-sectional views configurations of semiconductor devices according to an embodiment of the disclosed subject matter;

FIG. 15 is a cross-sectional view illustrating a configuration of a single chip package according to an embodiment of the disclosed subject matter;

FIG. 16 is a view illustrating an operation of the single chip package of FIG. 15;

FIGS. 17, 18, and 19 are lateral cross-sectional views illustrating configurations of single chip packages according to an embodiment of the disclosed subject matter;

FIGS. 20, 21, and 22 are lateral cross-sectional views illustrating configurations of multichip packages according to an embodiment of the disclosed subject matter;

FIGS. 23 and 24 are lateral cross-sectional views illustrating configurations of package-on-packages according to an embodiment of the disclosed subject matter;

FIGS. 25 and 26 are views illustrating a single chip package, and a cooling operation using one thermoelectric module of components of the single chip package; and

FIGS. 27, 28, and 29 are perspective views and system block diagrams illustrating electronic apparatuses according to embodiments of the disclosed subject matter.

### DETAILED DESCRIPTION OF THE EMBODIMENTS

Various embodiments will now be described more fully with reference to the accompanying drawings in which some embodiments are shown. The disclosed subject matter may, however, be embodied in different forms and should not be construed as limited to the embodiments set forth herein. Although a few embodiments of the inventive concept will be shown and described, it will be appreciated by those of ordinary skill in the art that changes may be made in these exemplary embodiments without departing from the principles and spirit of the inventive concept, the scope of which is defined by the claims and their equivalents.

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, items, steps, operations, elements, components, and/or group thereof, but do not preclude the presence or addition of one or more other features, items, steps, operations, elements, components, and/or groups thereof.

Terms such as “beneath,” “below,” “lower,” “above,” “upper” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation. Also, the device may reoriented in other ways (rotated 90 degrees or at other orientations) and the descriptors used herein should be interpreted accordingly.

Embodiments of the inventive concept are described herein with reference to cross-section and/or plan illustrations that are schematic illustrations of idealized embodiments of the inventive concept. In the drawings, the thicknesses of layers and regions are exaggerated for clarity. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the inventive concept.

Like numbers refer to like elements throughout. Thus, the same or similar numbers may be described with reference to other drawings even if they are neither mentioned nor described in the corresponding drawing. Also, even elements that are not denoted by reference numbers may be described with reference to other drawings.

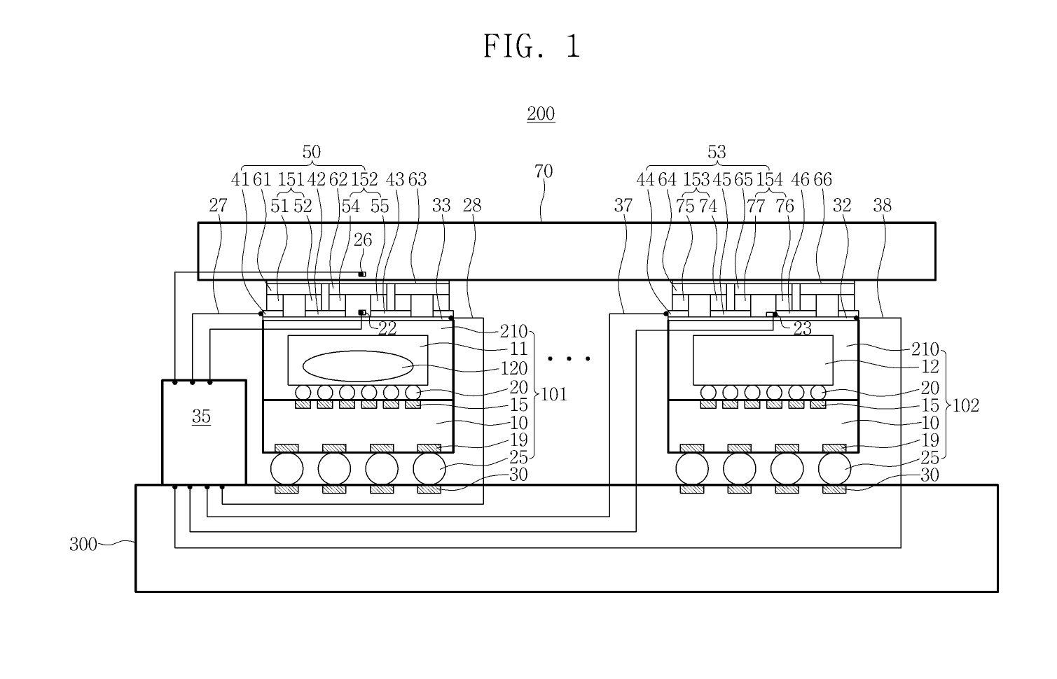

FIG. 1 is a cross-sectional view illustrating a configuration of a semiconductor device according to an embodiment of the disclosed subject matter.

Referring to FIG. 1, a semiconductor device 200 according to an embodiment of the disclosed subject matter may include a first semiconductor package 101, a second semiconductor package 102, a heat spreader 70, a first thermoelectric module 50, a second thermoelectric module 53, a first temperature sensor 22, a second temperature sensor 26, and a controller 35. The heat spreader 70 may be formed over the first and second semiconductor packages 101 and 102. The first thermoelectric module 50 may be formed between the first semiconductor package 101 and the head spreader 70. The second thermoelectric module 53 may be formed between the second semiconductor package 102 and the heat spreader 70. The first temperature sensor 22 may be formed between the first thermoelectric module 50 and the first semiconductor package 101. The second temperature sensor 26 may be formed between the heat spreader 70 and the first thermoelectric module 50. The first and second temperature sensors 22 and 26 may be electrically connected to the controller 35 and provide temperature information for a point of the first semiconductor package 101. A third temperature sensor 23 may be further included between the second semiconductor package 102 and the second thermoelectric module 53.

The semiconductor device 200 may determine the application of power to the first thermoelectric module 50 based on the temperature information received from the first temperature sensor 22. The semiconductor device 200 may determine the application of power to the second thermoelectric module 53 based on temperature information received from the second temperature sensor 26 and the third temperature sensor 23.

The first thermoelectric module 50 may receive a positive voltage through a first lead-in wire 27, and receive a negative voltage through a second lead-in wire 28.

The first thermoelectric module 50 may include a first thermoelectric pair 151 having a first P-type thermoelectric semiconductor element 51 and a first N-type thermoelectric semiconductor element 52 spaced apart from the first P-type thermoelectric semiconductor element 51. The first thermoelectric module 50 may include a second thermoelectric pair 152 having a second P-type thermoelectric semiconductor element 54 and a second N-type thermoelectric semiconductor element 55 spaced apart from the second P-type thermoelectric semiconductor element 54.

The first thermoelectric module 50 may include a first electrode 61 connected to the first P-type thermoelectric semiconductor element 51 and the first N-type thermoelectric semiconductor element 52 and disposed between the first thermoelectric pair 151 and the heat spreader 70. The first thermoelectric module 50 may include a second electrode 41 connected to the first P-type thermoelectric semiconductor element 51 and disposed between the first thermoelectric pair 151 and the first semiconductor package 101. The first thermoelectric module 50 may include a third electrode 42 connected to the first N-type thermoelectric semiconductor element 52 and the second P-type thermoelectric semiconductor element 54 and disposed between the first N-type thermoelectric semiconductor element 52 and the first semiconductor package 101, and between the second P-type thermoelectric semiconductor element 54 and the first semiconductor package 101. The first thermoelectric module 50 may include a fourth electrode 62 connected to the second P-type thermoelectric semiconductor element 54 and the second N-type thermoelectric semiconductor element 55 and disposed between the second thermoelectric pair 152 and the heat spreader 70. The first thermoelectric module 50 may include a fifth electrode 43 connected to the second N-type thermoelectric semiconductor element 55 and disposed between the second thermoelectric pair 152 and the first semiconductor package 101. Voltages may be applied to the second electrode 41 connected to the first P-type thermoelectric semiconductor element 51 and the third electrode 42 connected to the first N-type thermoelectric semiconductor element 52. Voltages may be applied to the second electrode 41 connected to the first P-type thermoelectric semiconductor element 51 and the fifth electrode 43 connected to the second N-type thermoelectric semiconductor element 55.

Here, in FIG. 1, forward activation may be defined as a case in which a positive voltage is applied through the first lead-in wire 27, and a negative voltage is applied through the second lead-in wire 28. And, reverse activation may be defined as a case in which a negative voltage is applied through the first lead-in wire 27, and a positive voltage is applied through the second lead-in wire 28.

The controller 35 may forward activate or reverse activate the first thermoelectric module 50 and the second thermoelectric module 53 according to the heat dissipation state of the first thermoelectric module 50, the second thermoelectric module 53, and the heat spreader 70.

A first insulating layer 33 may be formed between the first thermoelectric module 50 and the first semiconductor package 101. The first insulating layer 33 may prevent the first semiconductor package 101 and the first thermoelectric module 50 from being electrically connected. Heat generated in the first semiconductor package 101 may be absorbed through the first insulating layer 33 using the first thermoelectric module 50. The first insulating layer 33 may include a material having a relatively good electrical insulation and a relatively good thermal conductivity. The first insulating layer 33 may include a thermal interface material (TIM) layer. For example, the first insulating layer 33 may include aluminum oxide (Al₂O₃), zinc oxide (ZnO), a curable resin or epoxy-based resin to which a thermally transferable filler may be added, a fluorine resin, or a silicon-based thermal conductive resin. It is understood that the above are merely a few illustrative examples to which the disclosed subject matter is not limited. The first insulating layer 33 may be omitted.

A second insulating layer 63 may be disposed between the first thermoelectric module 50 and the heat spreader 70. The second insulating layer 63 may prevent the heat spreader 70 and the first thermoelectric module 50 from being electrically connected. Heat generated in the first thermoelectric module 50 may be transferred toward the heat spreader 70 through the second insulating layer 63. The second insulating layer 63 may include a material having a relatively good electrical insulation and a relatively good thermal conductivity. The second insulating layer 63 may include a TIM layer. For example, the second insulating layer 63 may include aluminum oxide (Al₂O₃), zinc oxide (ZnO), a curable resin or epoxy-based resin to which a thermally transferable filler may be added, a fluorine resin, or a silicon-based thermal conductive resin. It is understood that the above are merely a few illustrative examples to which the disclosed subject matter is not limited. The second insulating layer 63 may be omitted.

The first P-type thermoelectric semiconductor element 51 and the first N-type thermoelectric semiconductor element 52 may be disposed to be vertically aligned with respect to the first electrode 61 and the second electrode 41. The second electrode 41 and the first electrode 61 may be formed so that surfaces of the second electrode 41 and the first electrode 61, which are in contact with the first semiconductor package 101 and the heat spreader 70, are larger than lateral surfaces of the second electrode 41 and the first electrode 61.

The first semiconductor package 101 may include a first semiconductor chip 11, a substrate 10, bumps 20, and an encapsulant 210. The first semiconductor chip 11 may be mounted on the substrate 10 via the bumps 20. The bumps 20 may electrically connect the substrate 10 and the first semiconductor chip 11 through flip chip bonding. The bumps 20 may include a solder material.

For example, the substrate 10 may include a printed circuit board (PCB) for a package. The substrate 10 may be a board including a plurality of lower interconnections, and may include a rigid printed circuit board, a flexible printed circuit board, or a rigid-flexible printed circuit board. A plurality of bump lands 15 configured to electrically connect the substrate 10 and the first semiconductor chip 11 may be disposed on an upper surface of the substrate 10 to be exposed. Lower lands 19 may be disposed on a lower surface of the substrate 10. The lower lands 19 may include copper (Cu), nickel (Ni), gold (Au), or a solder material, etc.

The encapsulant 210 may cover lateral surfaces of the first semiconductor chip 11 and the bumps 20, and an upper surface of the first semiconductor chip 11. For example, the encapsulant 210 may include an epoxy molding compound (EMC).

External connection members 25 configured to electrically connect the first semiconductor package 101 to a mother board 300 may be formed on the lower lands 19. The external connection members 25 may be formed of a solder material, such as a solder ball, a solder bump, or a solder paste, or a metal having a spherical shape, a mesa shape, or a pin shape. The external connection member 25 may be formed in a grid form to implement a ball grid array (BGA) package.

The lower lands 19 may be electrically connected to finger electrodes 30 of the mother board 300 through the external connection members 25.

The second semiconductor package 102 may be electrically connected to the mother board 300. The second semiconductor package 102 may include a second semiconductor chip 12, bumps 20, and an encapsulant 210. The second semiconductor chip 12 may be mounted on the substrate 10. The second semiconductor chip 12 may be electrically connected to the substrate 10 via the bumps 20. The encapsulant 210 may be formed to cover lateral sides of the second semiconductor chip 12 and the bumps 20, and an upper surface of the second semiconductor chip 12.

It has been described that the first semiconductor package 101 may be a single chip package, but the first semiconductor package 101 may be replaced with other types of packages, such as a package-on-package (POP), a multichip package, a package-in-package, a system-in-package, a system-on-chip, a chip-on-board, a board-on-chip, or a semiconductor chip, such as a memory chip or a logic chip. For example, the first semiconductor package 101 may include a central processing unit (CPU) or an application processor. It is understood that the above are merely a few illustrative examples to which the disclosed subject matter is not limited.

The first semiconductor chip 11 may include a logic chip. The logic chip may include a high temperature region 120. When a temperature of the high temperature region 120 is not controlled, a heat problem (e.g., due to a high clock rate of the logic chip and/or increase in integration of a transistor, etc.) cannot be solved. As a countermeasure, the heat problem may be at least partially ameliorated through adjustment of a clock rate, voltage, and capacitance. However, due to the adjustment of the clock rate, voltage, and capacitance, degradation of performance may be caused and high performance cannot be performed.

As a countermeasure, a method of controlling heat generated in the first semiconductor chip 11 may be taken into consideration. The first thermoelectric module 50 may be formed close to the high temperature region 120 of the first semiconductor chip 11. The first temperature sensor 22 may be formed between the first thermoelectric module 50 and the first semiconductor package 101. A heating state of the first semiconductor chip 11 may be checked through the first temperature sensor 22,

The semiconductor device 200 according to an embodiment of the disclosed subject matter may set a temperature rise threshold value of the first semiconductor chip 11 and determine a first target temperature T1 from the threshold value. The first target temperature T1 may be a maximum temperature for showing performances of the semiconductor chips 11 and 12 without adjustment of a clock rate, voltage, and capacitance of the first semiconductor chip 11.

When an activation temperature of the first thermoelectric module 50 is set to T1, the semiconductor device may perform a cooling action at the temperature T1 or more. The first thermoelectric module 50 may be an element configured to absorb or emit heat according to a power supply.

Using the first thermoelectric module 50, it may be possible to reduce the temperature of the high temperature region 120 of the first semiconductor chip 11. A direct current (DC) power supply may be employed to drive or power the first thermoelectric module 50, and thus energy consumption may be increased. A control unit for the first thermoelectric module 50 may be used to minimize the use of the power according to the first thermoelectric module 50.

When a temperature measured in the first temperature sensor 22 is equal to or larger than the first target temperature T1, a positive (+) bias may be applied to the second electrode 41 connected to the first P-type thermoelectric semiconductor element 51, and a negative (−) bias may be applied to the third electrode 42 connected to the first N-type thermoelectric semiconductor element 52. Alternatively, a positive (+) bias may be applied to the second electrode 41 connected to the first P-type thermoelectric semiconductor element 51, and a negative (−) bias may be applied to the fifth electrode 43 connected to the second N-type thermoelectric semiconductor element 55.

When the temperature measured in the first temperature sensor 22 is less than the first target temperature T1, the voltages may be removed from the second electrode 41 connected to the first P-type thermoelectric semiconductor element 51 and the third electrode 42 connected to the first N-type thermoelectric semiconductor element 52, or the voltages applied to the second electrode 41 connected to the first P-type thermoelectric semiconductor element 51 and the fifth electrode 43 connected to the second N-type thermoelectric semiconductor element 55.

When the first thermoelectric module 50 is driven or powered, heat absorption may occur at a side of the first thermoelectric module 50 close to the first semiconductor chip 11, and a heat generation occurs at a side of the first thermoelectric module 50 close to the heat spreader 70. When the first thermoelectric module 50 is thermally connected to one side of the heat spreader 70, the second thermoelectric module 53 may be formed to the other side of the heat spreader 70.

The second temperature sensor 26 may be included between the heat spreader 70 and the first thermoelectric module 50. The second temperature sensor 26 may be electrically connected to the controller 35 to measure a temperature of the heat spreader 70. The second thermoelectric module 53 may be used as a control unit for heat transferred from the heat spreader 70. The second thermoelectric module 53 may receive a positive voltage from the controller 35 through the third lead-in wire 37, and receive a negative voltage from the controller 35 through the fourth lead-in wire 38.

The second thermoelectric module 53 may include a third thermoelectric pair 153 having a third N-type thermoelectric semiconductor element 75 and a third P-type thermoelectric semiconductor element 74 spaced apart from the third N-type thermoelectric semiconductor element. The second thermoelectric module 53 may include a fourth thermoelectric pair 154 having a fourth N-type thermoelectric semiconductor element 77 and a fourth P-type thermoelectric semiconductor element 76 spaced apart from the fourth N-type thermoelectric semiconductor element. A third insulating layer 32 may be formed between the third thermoelectric pair 153 and the second semiconductor package 102. The fourth insulating layer 66 may be formed between the second thermoelectric module 53 and the heat spreader 70. The third insulating layer 32 and the fourth insulating layer 66 may include a material having good heat transfer performance.

The second thermoelectric module 53 may include a sixth electrode 64 connected to the third N-type thermoelectric semiconductor element 75 and the third P-type thermoelectric semiconductor element 74 and disposed between the third thermoelectric pair 153 and the heat spreader 70. The second thermoelectric module 53 may include a seventh electrode 44 connected to the third N-type thermoelectric semiconductor element 75 and disposed between the third thermoelectric pair 153 and the second semiconductor package 102. The second thermoelectric module 53 may include an eighth electrode 45 connected to the third P-type thermoelectric semiconductor element 74 and the fourth N-type thermoelectric semiconductor element 77 and disposed between the third P-type thermoelectric semiconductor element 74 and the second semiconductor package 102, and between the fourth N-type thermoelectric semiconductor element 77 and the second semiconductor package 102. The second thermoelectric module 53 may include a ninth electrode 65 connected to the fourth N-type thermoelectric semiconductor element 77 and the fourth P-type thermoelectric semiconductor element 76 and disposed between the fourth thermoelectric pair 154 and the heat spreader 70. The second thermoelectric module 53 may include a tenth electrode 46 connected to the fourth P-type thermoelectric semiconductor element 76 and disposed between the fourth thermoelectric pair 154 and the second semiconductor package 102. Voltages may be applied through the seventh electrode 44 connected to the third N-type thermoelectric semiconductor element 75 and the eighth electrode 45 connected to the third P-type thermoelectric semiconductor element 74. Alternatively, voltages may be applied through the seventh electrode 44 connected to the third N-type thermoelectric semiconductor element 75 and the tenth electrode 46 connected to the fourth P-type thermoelectric semiconductor element 76.

When a temperature measured in the second temperature sensor 26 is equal to or larger than a second target temperature T2, a positive (+) bias may be applied to the seventh electrode 44 connected to the third N-type thermoelectric semiconductor element 75, and a negative (−) bias may be applied to the eighth electrode 45 connected to the third P-type thermoelectric semiconductor element 74 or the tenth electrode 46 connected to the fourth P-type thermoelectric semiconductor element 76.

When the temperature measured in the second temperature sensor 26 is less than the second target temperature T2, the voltage may be removed from the seventh electrode 44 connected to the third N-type thermoelectric semiconductor element 75, and the voltage applied to the eighth electrode 45 connected to the third P-type thermoelectric semiconductor element 74, or the tenth electrode 46 connected to the fourth P-type thermoelectric semiconductor element 76.

As illustrated in FIG. 1, current may flow from the seventh electrode 44 to the eighth electrode 45 connected to the third P-type thermoelectric semiconductor element 74 via the third N-type thermoelectric semiconductor element 75 electrically connected to the seventh electrode 44, the sixth electrode 64 electrically connected to the third N-type thermoelectric semiconductor element 75, and the third P-type thermoelectric semiconductor element 74 electrically connected to the sixth electrode 64. This driving state may be referred to as reverse activation. A heat absorption portion and a heat generation portion of the thermoelectric modules 50 and 53 may be changed according to the states of the forward activation and the reverse activation.

A temperature of the heat spreader 70 may be reduced by the activation of the second thermoelectric module 53. When the temperature of the heat spreader 70 is reduced, heat transferred to the heat spreader 70 from the first thermoelectric module 50 may dissipate quickly. The first thermoelectric module 50, the heat spreader 70, and the second thermoelectric module 53 are combined to be used as a heat pump.

When a temperature measured in the third temperature sensor 23 is equal to or larger than the first target temperature T1, a negative (−) bias may be applied to the seventh electrode 44 connected to the third N-type thermoelectric semiconductor element 75, and a positive (+) bias may be applied to the eighth electrode 45 connected to the third P-type thermoelectric semiconductor element 74 or the tenth electrode 46 connected to the fourth P-type thermoelectric semiconductor element 76. As described above, when the second thermoelectric module 53 which is in the reverse activation is transitioned to the forward activation, a temperature of the heat spreader 70 thermally connected to the second thermoelectric module 53 may be increased. A temperature of the second semiconductor package 102 connected to the second thermoelectric module 53 may be reduced.

When the temperature measured in the third temperature sensor 23 is less than the first target temperature T1, the voltage applied to the seventh electrode 44 connected to the third N-type thermoelectric semiconductor element 75 and the voltage applied to the eighth electrode 45 connected to the third P-type thermoelectric semiconductor element 74 or the tenth electrode 46 connected to the fourth P-type thermoelectric semiconductor element 76 may be removed. A process of optimizing an operation of the semiconductor device 200 having the thermoelectric modules 50 and 53 according to the disclosed subject matter through the above-described action will be described later.

In the semiconductor device 200 according to an embodiment of the disclosed subject matter, as a temperature difference between a contact portion between the first thermoelectric module 50 and the heat spreader 70 and a contact portion between the second thermoelectric module 53 and the heat spreader 70 is increased, heat emission efficiency in the first thermoelectric module 50 may be increased. When heat transfer efficiency is increased, the first thermoelectric module 50 may reduce the temperature of the first semiconductor chip 11 to under T1 and maintain normal activation of the first semiconductor package 101 easily. Many thermoelectric modules may be used to maintain the normal activation of the first semiconductor package 101. Using many thermoelectric modules, operation efficiency of the first thermoelectric module 50 may be increased, and activation performance of the first semiconductor chip 11 may be improved. Driving of the heat spreader 70, the first thermoelectric module 50, and the first semiconductor chip 11 may be optimized using a plurality of thermoelectric modules 50 and 53. Further, the first semiconductor chip 11 may be made to operate in a temperature range (for example, below T1) through temperature setting of the operation of the first semiconductor chip 11. The principle may be applied to the heat spreader 70 (for example, below T2) equally.

The heat spreader 70 may have an adhesive. The heat spreader 70 may include a material having good thermal conductivity. For example, the heat spreader 70 may include copper (Cu), silver (Ag), gold (Au), platinum (Pt), tin (Sn), aluminum (Al), or an alloy thereof. It is understood that the above are merely a few illustrative examples to which the disclosed subject matter is not limited.

The second semiconductor chip 12 may be a memory chip such as a volatile memory or a nonvolatile memory. For example, each of the first semiconductor chip 11 and the second semiconductor chip 12 may include a mobile dynamic random access memory (DRAM).

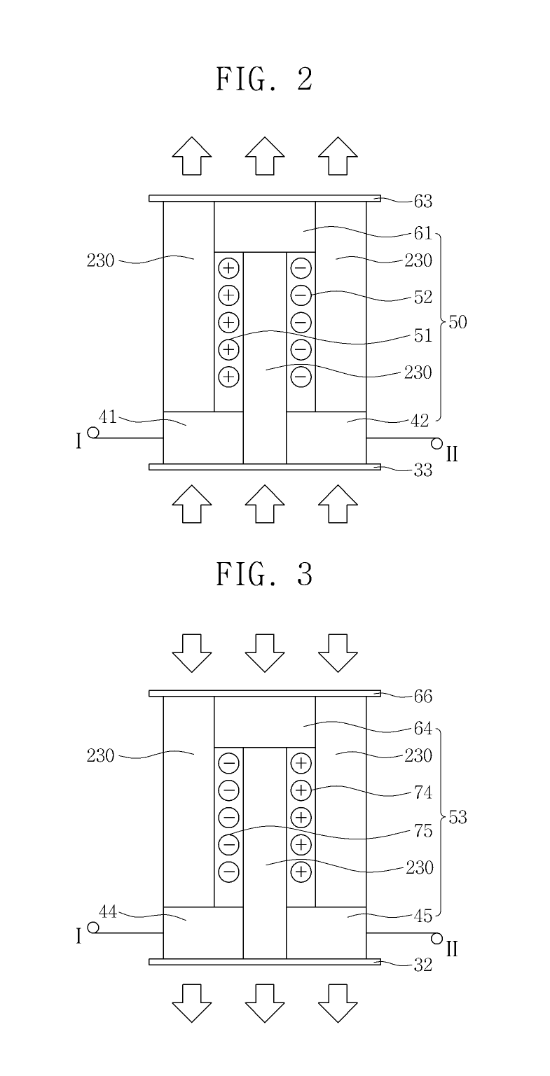

FIGS. 2 and 3 are views explaining forward activation and reverse activation of a thermoelectric module used in a semiconductor device according to the disclosed subject matter. Referring to FIG. 2, the first thermoelectric module 50 included in the semiconductor device 200 according to an embodiment of the disclosed subject matter may include the second electrode 41 to which a positive voltage is supplied, the first P-type thermoelectric semiconductor element 51, the first electrode 61, the first N-type thermoelectric semiconductor element 52, and the third electrode 42 to which a negative voltage is supplied. An insulating resin 230 may be disposed between the first P-type thermoelectric semiconductor element 51 and the first N-type thermoelectric semiconductor element 52. For example, the insulating resin 230 may include a material having low thermal conductivity such as parylene or photoresist. The insulating resin 230 may be omitted.

In the semiconductor device 200 according to the disclosed subject matter, a negative voltage may be applied in the middle of positive voltage application. For clarity, it is limited and described in FIGS. 2 and 3 that a positive electrode is connected to a first or I side, and a negative electrode is connected to a second or II side.

The first P-type thermoelectric semiconductor element 51 may be electrically connected to the second electrode 41. The first electrode 61 may be electrically connected to the first P-type thermoelectric semiconductor element 51. Since the first P-type thermoelectric semiconductor element 51 contains holes more than an intrinsic semiconductor, the first P-type thermoelectric semiconductor element 51 may be indicated as a symbol “+”. For example, the first P-type thermoelectric semiconductor element may contain boron (B).

By operation of direct current (DC) power supply, holes may be generated in the second electrode 41 and supplied to the first P-type thermoelectric semiconductor element 51, and flow of the holes from the first P-type thermoelectric semiconductor element 51 to the first electrode 61 may be derived. The first N-type thermoelectric semiconductor element 52 may be electrically connected to the first electrode 61. Since the first N-type thermoelectric semiconductor element 52 contains electrons more than an intrinsic semiconductor, the first N-type thermoelectric semiconductor element 52 may be indicated in a symbol “−”. The first N-type thermoelectric semiconductor element may contain phosphor (P) or arsenic (As).

Electrons may be generated in the third electrode 42 and supplied to the first N-type thermoelectric semiconductor element 52. The electrons may be supplied to the first electrode 61 from the first N-type thermoelectric semiconductor element 52.

The holes and the electrons meet in the first electrode 61 to cause heat generation. Since the holes and electrons are generated in the second electrode 41 and the third electrode 42 and simultaneously move the first P-type thermoelectric semiconductor element 51 and the first N-type thermoelectric semiconductor element 52, heat may move along with the holes. Through the above-described process, heat generated in the first semiconductor package 101 may be absorbed in the first thermoelectric module 50 as electric energy, and electric energy generated in the first thermoelectric module 50 may be emitted towards the heat spreader 70 as thermal energy.

The semiconductor device 200 according to the disclosed subject matter may include an active control mechanism which converts heat generated in the semiconductor packages 101 and 102 into electric energy, and converts electric energy generated in the first thermoelectric module 50 into heat energy in the heat spreader 70. Using the active control mechanism, it may prevent temperatures of the semiconductor package 101 and 102 from being increased above a specific level. It may also prevent a temperature of the heat spreader from being increased above a specific level. On the contrary, a temperature of the heat spreader 70 may be reduced using the active control mechanism. The thermoelectric modules may abnormally operate in the high temperature portions thereof rather than in the low temperature portions thereof. Therefore, as described above, when the high temperature portions and the low temperature portions of the thermoelectric modules are controlled, operation efficiency of the thermoelectric modules 50 and 53 may be maximized.

Referring to FIG. 3, the second thermoelectric module 53 included in the semiconductor device 200 according to an embodiment of the disclosed subject matter may include the seventh electrode 44 to which a positive voltage is supplied, the third P-type thermoelectric semiconductor element 74, the sixth electrode 64, the third N-type thermoelectric semiconductor element 75, and the eighth electrode 45 to which a negative voltage is supplied. An insulating resin 230 may be disposed between the third P-type thermoelectric semiconductor element 74 and the third N-type thermoelectric semiconductor element 75. For example, the insulating resin 230 may include a material having low thermal conductivity such as parylene or photoresist. It is understood that the above are merely a few illustrative examples to which the disclosed subject matter is not limited.

The third N-type thermoelectric semiconductor element 75 may be electrically connected to the seventh electrode 44. The sixth electrode 64 may be electrically connected to the third N-type thermoelectric semiconductor element 75.

By operation of a DC power supply, holes may be generated in the sixth electrode 64 and supplied to the third P-type thermoelectric semiconductor element 74, and flow of the holes from the third P-type thermoelectric semiconductor element 74 to the eighth electrode 45 may be derived. Electrons may be generated in the sixth electrode 64 and supplied to the third N-type thermoelectric semiconductor element 75, and flow of the electrons from the third N-type thermoelectric semiconductor element 75 to the seventh electrode 44 may be derived.

The electrons and the holes may meet in the seventh electrode 44 to generate heat. The holes and the electrons may meet in the eighth electrode 45 to generate heat.

The heat absorption in which electrons and holes are generated may occur in the sixth electrode 64. Since the holes and the electrons may move from the third P-type thermoelectric semiconductor element 74 and the third N-type thermoelectric semiconductor element 75, and are combined in the seventh electrode 44 and the eighth electrode 45, it may be considered that heat moves along with the holes and electrodes.

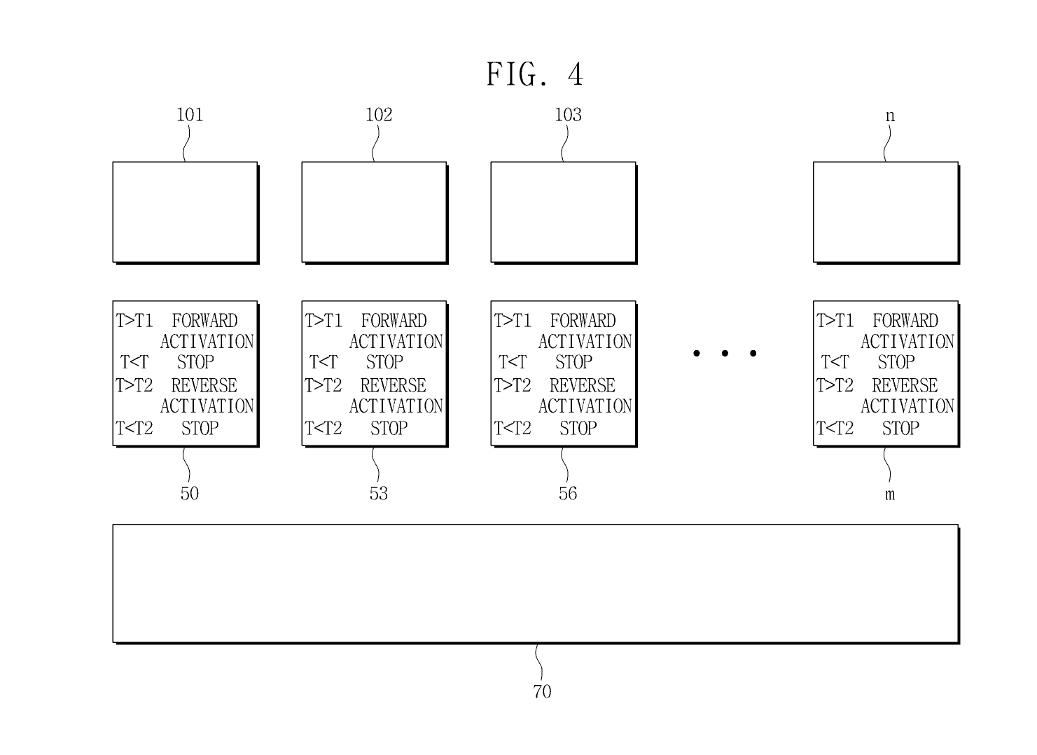

FIG. 4 is a view illustrating a technique for controlling a semiconductor device according to an embodiment of the disclosed subject matter. Referring to FIG. 4, integrated circuit (IC) power for driving the semiconductor device 200 according to an embodiment of the disclosed subject matter may be applied. Semiconductor packages 101, 102, 103, . . . , n may operate according to application of the IC power. The heat spreader 70 may be formed on the semiconductor packages 101, 102, 103, . . . , n. A plurality of thermoelectric modules 50, 53, 56, . . . , m may be disposed between the semiconductor packages 101, 102, 103, . . . , n and the heat spreader 70 to form an array.

Temperature sensors 22 and 23 may be formed in high temperature portions on the thermoelectric modules 50, 53, 56, . . . , m. In the disclosed subject matter, portions of the thermoelectric modules which are located close to the semiconductor packages may be defined as a high temperature portion of the thermoelectric module, and portions of the thermoelectric modules which are located closed to the heat spreader may be defined as the low temperature portion. Through the operations of the temperature sensors 22 and 23, temperatures of the semiconductor packages 101, 102, 103, . . . , n may be measured in real time.

A portion of the semiconductor packages 101, 102, 103, . . . , n, of which a temperature is increased most rapidly, may be checked through the first temperature sensor 22 attached to each of the thermoelectric modules 50, 53, 56, . . . , m in real time. When a temperature measured in the first temperature sensor 22 is equal to or greater than a first target temperature (here, it is assumed that the first target temperature is T1), a thermoelectric module, which is installed in a semiconductor package of which a temperature is increased to above the first target temperature, may be forwardly activated.

The temperature of the semiconductor package having the first target temperature or more among the semiconductor packages 101, 102, 103, . . . , n mounted with the thermoelectric modules 50, 53, 56, . . . , m may be reduced according to the forward activation of the thermoelectric module.

Since the second temperature sensor 26 is formed in the heat spreader 70, a temperature of the heat spreader 70 may be checked in real time. When the temperature of the heat spreader 70 is increased to arrive at a second target temperature (here, it is assumed that the second target temperature is T2), other thermoelectric modules may be reversely activated other than the thermoelectric module which is in the forward activation.

The temperature of the heat spreader 70 may be reduced according to the reverse activation of the other thermoelectric modules. The temperature of the heat spreader 70 may be measured and controlled so that the thermoelectric module which is in the forward activation among the thermoelectric modules shows its performance. At this time, the temperature of the heat spreader 70 may be relatively further reduced according to a control condition (reverse activation of a plurality of thermoelectric modules). When the temperature of the heat spreader 70 is reduced, the thermoelectric module which is in forward activation may actively reduce the temperature of the semiconductor package which operates at a temperature of above T1.

When a temperature measured in the thermoelectric module which is in forward activation becomes equal to or less than T1, the thermoelectric module which is in forward activation may be stopped. When a temperature of the heat spreader mounted with the thermoelectric modules which are in reverse activation becomes equal to or less than T2, the thermoelectric modules which are in reverse activation may be stopped. At this time, a stop temperature of the thermoelectric modules which are in reverse activation and mounted on the heat spreader 70 may be further reduced to improve efficiency, and thus operation efficiency of the thermoelectric module which is in forward activation may be improved. Further, the cooling speed of the heat spreader 70 may be increased by reversely activating a large number of thermoelectric modules.

Temperatures of high temperature portions of the thermoelectric modules installed in other semiconductor packages in which temperatures measured in the thermoelectric modules are equal to or less than T1 may be increased according to the reverse activation of the thermoelectric modules. When the temperatures of the high temperature portions of the thermoelectric modules are equal to or larger than T1, the thermoelectric modules which are in the reverse activation are transitioned to the forward activation.

At a time, when the temperature of the heat spreader 70 is equal to or larger than T2, and the temperatures of the high temperature portions of the thermoelectric modules 50, 53, 56, . . . , m which are in the reverse activation and connected to the semiconductor packages among the semiconductor packages are equal to or larger than T1, forward activation of the thermoelectric modules 50, 53, 56, . . . , m may be first performed.

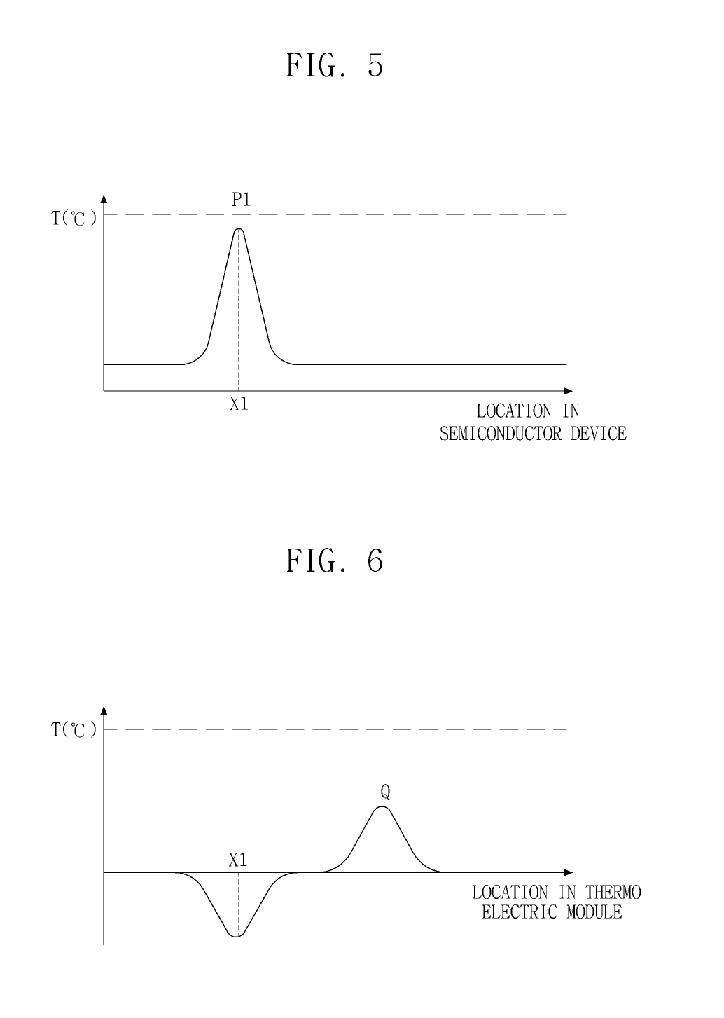

FIGS. 5, 6, and 7 are graphs illustrating control of heat generated in the semiconductor packages 101 and 102 using thermoelectric modules.

Referring to FIG. 5, a temperature at a location X1 of the high temperature region 120 of the semiconductor device 200 may be increased to a point P1 according to application of IC power. As illustrated in FIG. 5, when temperatures of other locations may be maintained to room temperature. When the highest temperature in which the semiconductor device 200 can operate with error is T in FIG. 5, the semiconductor device 200 may not operate normally when the temperature of the semiconductor device 200 arrives at T ° C. To prevent this in advance, a cooling operation may be derived using the first thermoelectric module 50 before the temperature in the location X1 of the semiconductor device 200 arrives at T ° C.

FIG. 6 shows temperature distribution according to a location of the thermoelectric module. Since the thermoelectric module operates through external power, a portion of the thermoelectric module in which heat absorption occurs may be disposed close to the semiconductor device 200. To maximize operation efficiency of the thermoelectric module, the thermoelectric module may be disposed in an X1 point which is a location corresponding to the semiconductor device 200.

At this time, since the thermoelectric module causes heat generation as well as heat absorption, a Q point as illustrated in FIG. 6 may be generated in the thermoelectric module. The Q point may be a portion of the thermoelectric module which causes the heat generation.

According to the semiconductor device 200 having the thermoelectric module of the disclosed subject matter, the Q point may be formed at a point close to the heat spreader 70. Since the thermoelectric module is a device which does not normally operate in a high temperature, the thermoelectric module may smoothly operate by lowering the temperature of the Q point at high speed. To reduce the temperature of the Q point, other thermoelectric modules on the heat spreader 70, which are not forwardly activated, may be reversely activated.

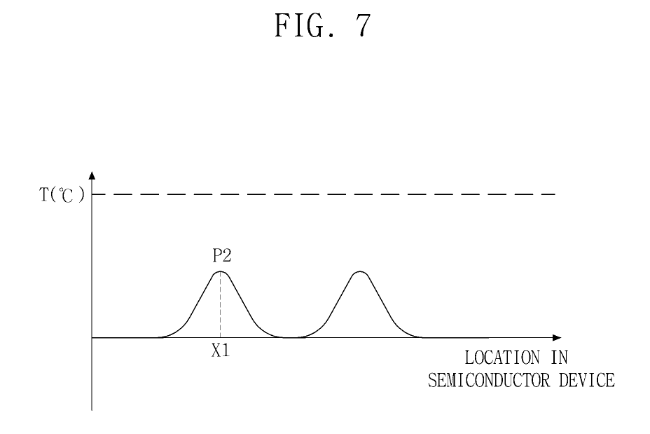

FIG. 7 is a view illustrating that a thermoelectric module is forwardly activated with respect to the semiconductor package 101 having the high temperature region 120 to reduce a temperature of the high temperature region 120, and a thermoelectric module is reversely activated with respect to the thermoelectric module installed in the semiconductor package 102 have no high temperature region.

Referring to FIG. 7, a temperature may be reduced to P2 at an X1 point which is in the high temperature region 120 within the semiconductor device 200. On the other hand, temperatures in other semiconductor packages within the semiconductor device 200 may be increased. Since an IC has a property in which the IC does not perform a normal operation at a specific temperature (for example, T in FIGS. 5, 6, and 7) or more, a thermoelectric module array may be controlled in the direction of reducing a temperature difference between the package 101 having the high temperature region 120 and the package 102 having the low temperature region through control of the thermoelectric module array. The temperature is regulated within a sweet spot in which a sum of dynamic power and leakage power is minimized

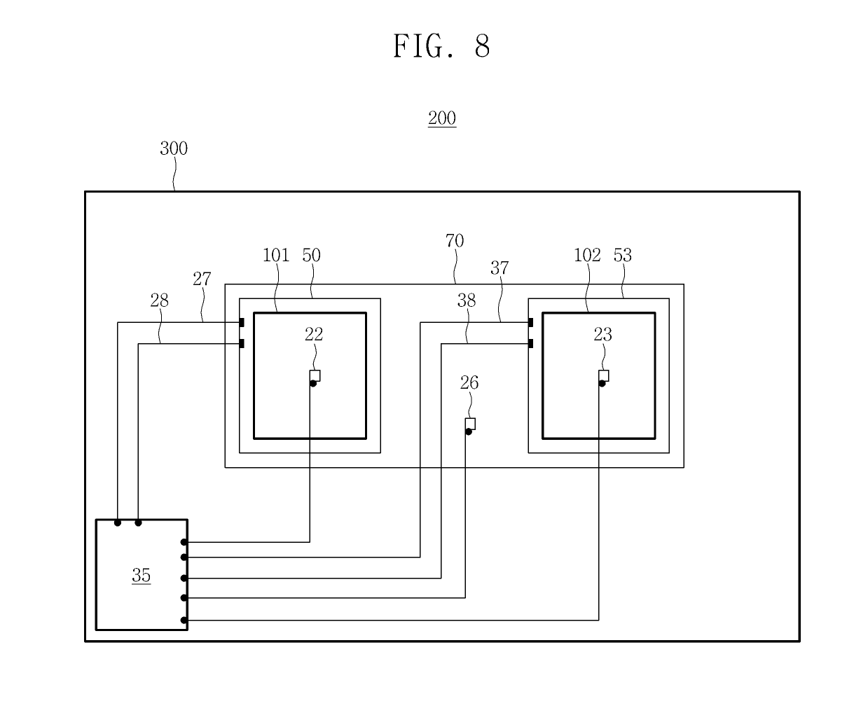

FIGS. 8, 9, 10, and 11 are plan views other configurations of a thermoelectric module in a semiconductor package according to an embodiment of the disclosed subject matter.

Referring to FIG. 8, a semiconductor device 200 may include a first semiconductor package 101 and a second semiconductor package 102. A first thermoelectric module 50 may be formed on an upper surface of the first semiconductor package 101. A second thermoelectric module 53 may be formed on an upper surface of the second semiconductor package 102. The first thermoelectric module 50 may be thermally connected to the second thermoelectric module 53 through a heat spreader 70. The first thermoelectric module 50 may receive a positive voltage through a first lead-in wire 27, and receive a negative voltage through a second lead-in wire 28. As described in FIG. 2, heat absorption may occur in a side of the first semiconductor package 101. Heat generation may occur in a side of the heat spreader 70. The heat spreader 70 is configured of a material having good thermal conductivity, and thus reaches at the same temperature within a short time. At this time, the second thermoelectric module 53 may be reversely activated. A positive voltage is supplied to the thermoelectric module 53 through a third lead-in wire 37, and a negative voltage may be supplied to the second thermoelectric module 53 through a fourth lead-in wire 38. The heat spreader 70 may be cooled according to the reverse activation of the second thermoelectric module 53. Therefore, a temperature difference may be generated between a portion of the heat spreader 70 in which the first thermoelectric module 50 is located and a portion of the heat spreader 70 in which the second thermoelectric module 53 is located. Heat generated in the first thermoelectric module 50 is transferred to the second thermoelectric module 53 through the heat spreader 70 and the first thermoelectric module 50 may be cooled.

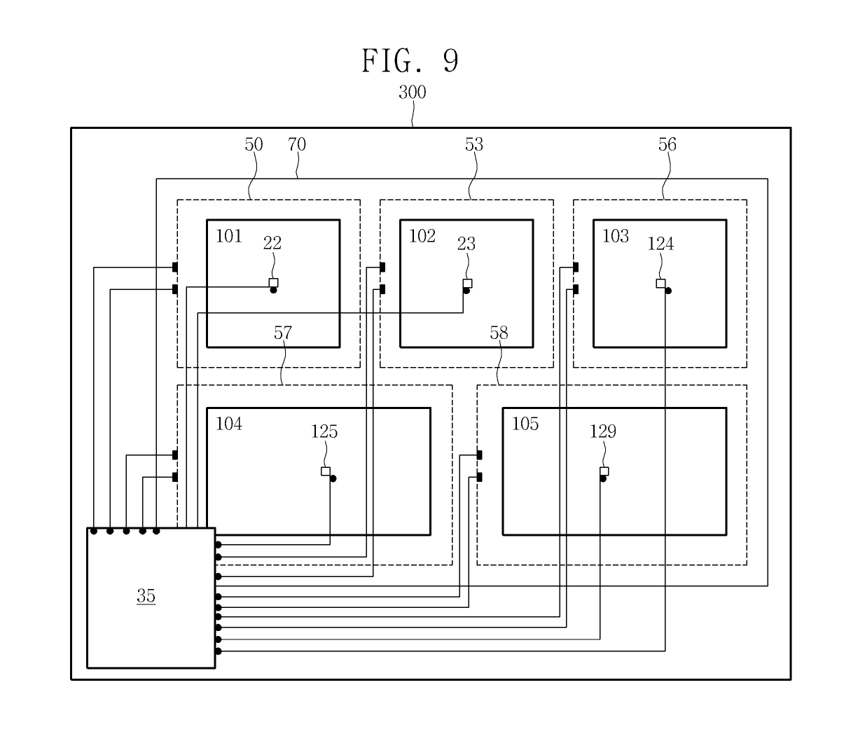

Referring to FIG. 9, a semiconductor device according to an embodiment of the disclosed subject matter may include a plurality of packages 101, 102, 103, 104, and 105, a heat spreader 70, and thermoelectric modules 50, 53, 56, 57, and 58. The plurality of semiconductor packages 101, 102, 103, 104, and 105 may be mounted on a mother board 300. The heat spreader 70 may be formed on the semiconductor packages 101, 102, 103, 104, and 105. The thermoelectric modules 50, 53, 56, 57, and 58 may be formed between the heat spreader 70 and the semiconductor packages 101, 102, 103, 104, and 105.

Temperature sensors 22, 23, 124, 125, and 129 may be formed between the semiconductor packages 101, 102, 103, 104, and 105 and the thermoelectric modules 50, 53, 56, 57, and 58

As illustrated in FIG. 9, the thermoelectric modules 50, 53, 56, 57, and 58 are divided by a dotted section, and thus individual supply of power is possible. The thermoelectric modules 50, 53, 56, 57, and 58 may drain heat from the semiconductor packages 101, 102, 103, 104, and 105, or transfer heat to the semiconductor packages 101, 102, 103, 104, and 105 according to a supply form of power.

A point, in which the highest temperature occurs in each of the semiconductor packages 101, 102, 103, 104, and 105, may be checked using the temperature sensors 22, 23, 124, 125, and 129. The point in which the highest temperature occurs may be referred to as a high temperature region. The thermoelectric modules 50, 53, 56, 57, and 58 are activated with the respect to the high temperature regions, and thus the temperatures of the high temperature regions 120 may be controlled.

Other thermoelectric modules 50, 53, 56, 57, and 58 may be reversely activated to reduce the temperature on the point including the high temperature region 120 effectively.

For example, the point, in which the highest temperature occurs among the semiconductor packages 101, 102, 103, 104, and 105 mounted on the mother board 300, may be found through the temperature sensors 22, 23, 124, 125, and 129 in FIG. 9. From the found temperature information of the semiconductor packages 101, 102, 103, 104, and 105, it may allow the heat to be drained from the semiconductor package 101, 102, 103, 104, and 105 having the high temperature regions 120. The thermoelectric modules 50, 63, 56, 57, and 58 may be activated so that the temperature of the semiconductor package having the highest temperature among the semiconductor packages 101, 102, 103, 104, and 105, is reduced, and polarities of other thermoelectric modules among the thermoelectric modules 50, 53, 56, 57, and 58 other than the thermoelectric module corresponding to the semiconductor package having the highest temperature may be reversed. Through the operations, the temperatures of the semiconductor packages having the high temperature regions 120 may be reduced, and the temperature of the heat spreader 70 may be increased. Through the above-described method, while the power consumption is minimized, the management of the semiconductor packages 101, 102, 103, 104, and 105 having the high temperature regions 120 may be smoothly performed. Although not described, when the semiconductor packages 101, 102, 103, 104, and 105 are managed through the above-described method, the efficient management may be performed even when the point which is the high temperature region 120 is changed. Since increase in the temperature of the heat spreader 70 is prevented, the temperature around the thermoelectric modules 50, 53, 56, 57, and 58 connected to the semiconductor packages 101, 102, 103, 104, and 105 showing the highest temperature may be prevented and thus the thermoelectric modules 50, 53, 56, 57, and 58 may smoothly operate.

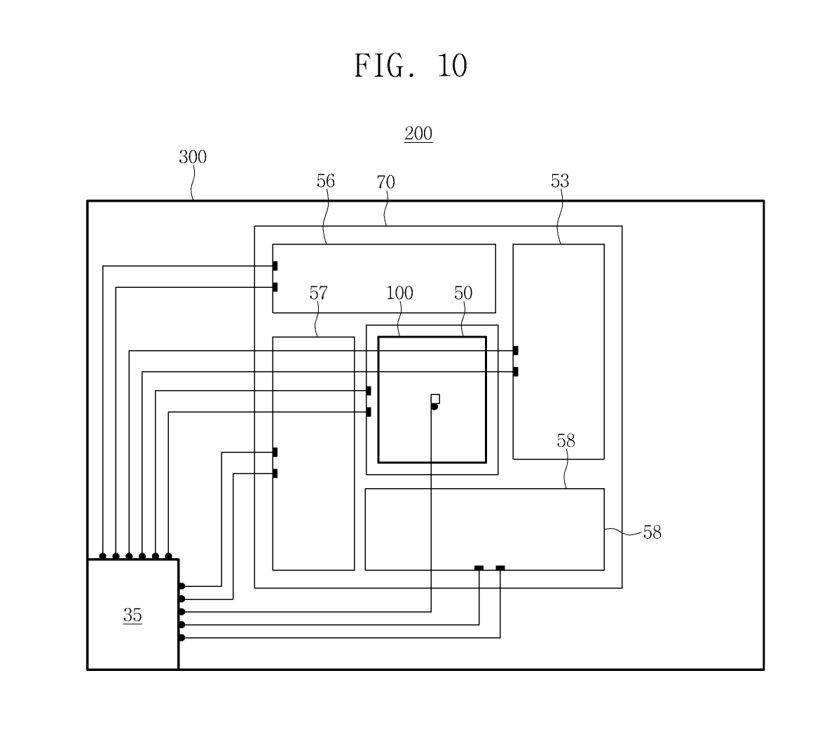

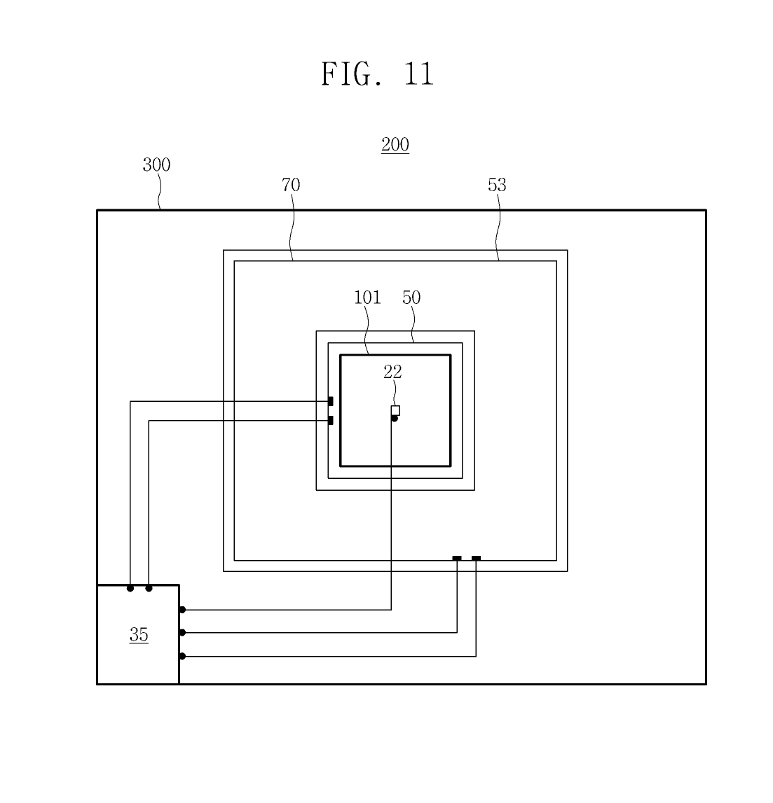

Referring to FIG. 10, a semiconductor package 100 may be formed in a central portion. The semiconductor package 100 may be a semiconductor package showing the highest temperature among a plurality of semiconductor packages 100.

A plurality of thermoelectric modules 53, 56, 57, and 58 are connected to a periphery of the semiconductor package 100 to manage an operation of the semiconductor package 100 efficiently. The heat management method may be the same as described in FIG. 4.

An example in which four thermoelectric modules 53, 55, 57, and 58 are used is limited in FIG. 10, but the disclosed subject matter is not limited thereto.

Referring to FIG. 11, a first thermoelectric module 50 installed over the first semiconductor package 101 and a second thermoelectric module 53 occupying a wide area in a periphery of the first thermoelectric module 50 may be formed. Since an amount of heat absorption and an amount of heat generation are proportional to an amount of current, a heat absorption area may be increased by increasing an area of the second thermoelectric module 53 with respect to the first thermoelectric module 50. When the first semiconductor package 100 starts to overheat, the first thermoelectric module 50 may be forwardly activated. The first thermoelectric module 50 may be overheated due to a continuous cooling operation to the first semiconductor package 101. An overheated low temperature portion of the first thermoelectric module 50 may be thermally connected to a low temperature portion of the second thermoelectric module 53 through a heat spread 70. The overheated low temperature portion of the first thermoelectric module 50 may be cooled due to reverse activation of the second thermoelectric module 53 having the wide heat absorption area. Under the configuration of FIG. 11, when a heat generation portion of the semiconductor package 101 is fixed, the thermoelectric module may function as an efficient cooling unit.

The overheating of the first thermoelectric module 50 may be controlled through the heat spreader 70 and the second thermoelectric module 53 thermally connected to the heat spreader 70.

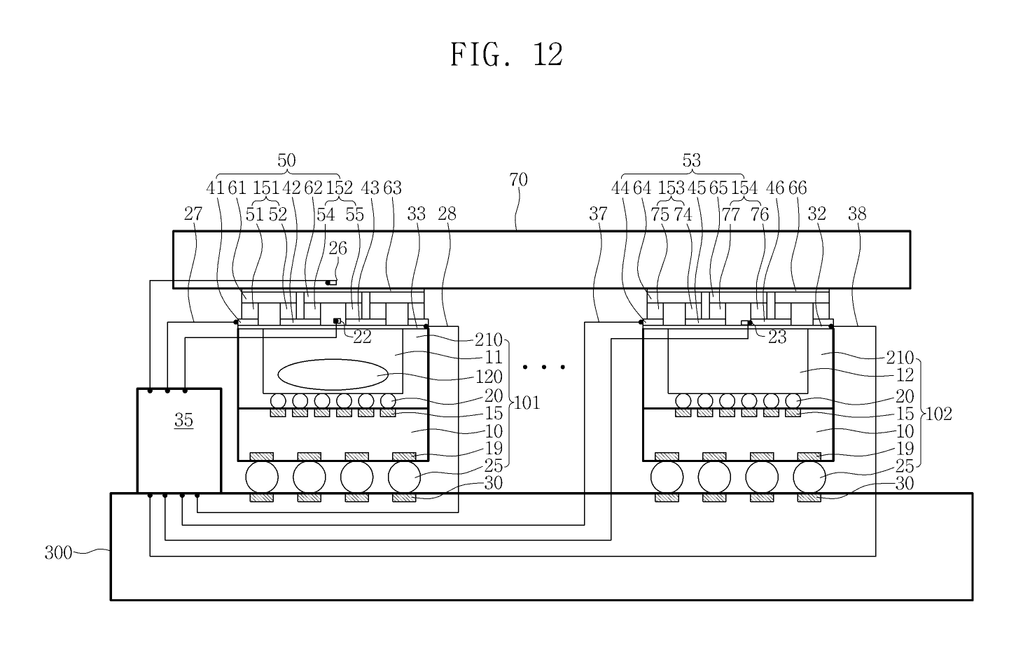

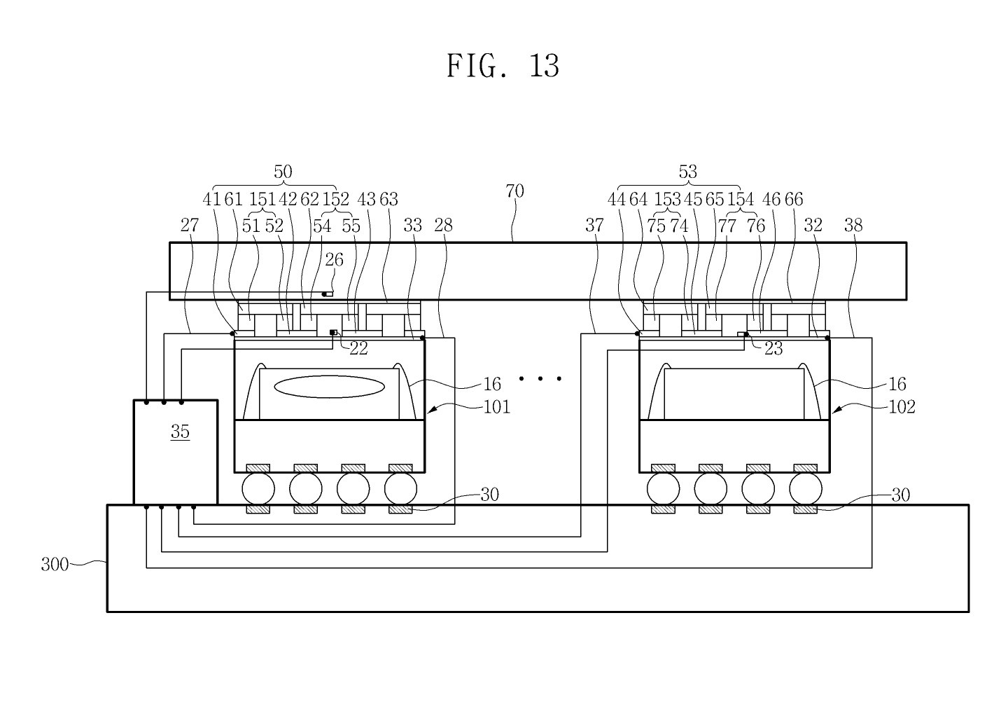

FIGS. 12, 13, and 14 are cross-sectional views illustrating configurations of semiconductor devices according to an embodiment of the disclosed subject matter.

Referring to FIG. 12, upper surfaces of a first semiconductor chip 11 and a second semiconductor chip 12 may be formed to the same height as upper surfaces of encapsulants 210. The upper surfaces of the first semiconductor chip 11 and the second semiconductor chip 12 are exposed to be in contact with the first thermoelectric module 50 and the second thermoelectric module 53.

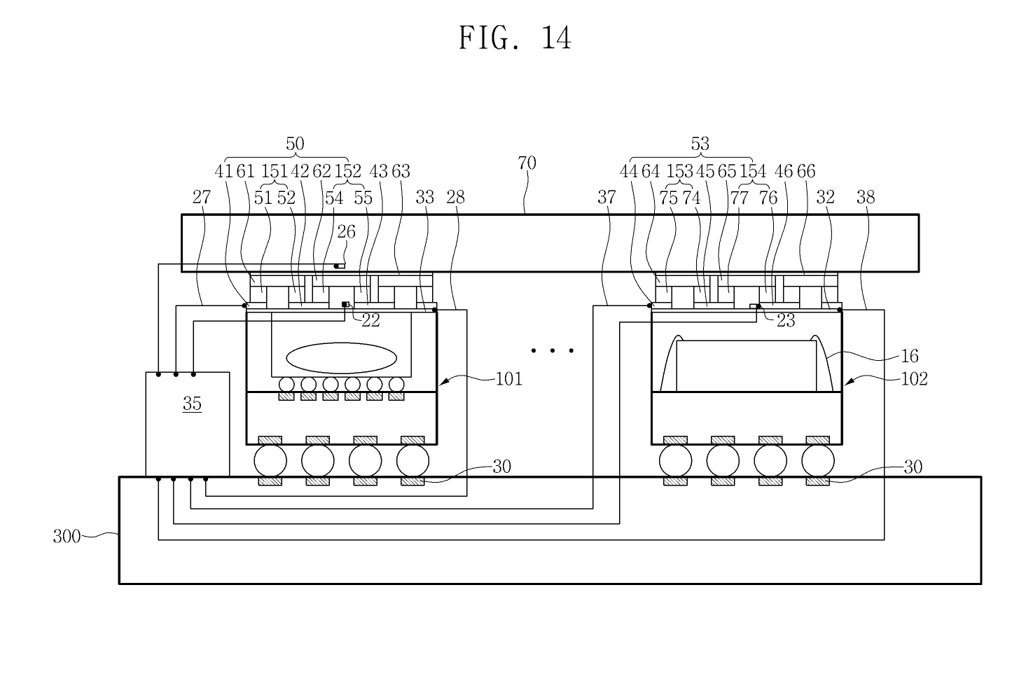

FIG. 13 is a cross-sectional view illustrating a configuration of a semiconductor device according to an embodiment of the disclosed subject matter.

Referring to FIG. 13, a semiconductor device 200 according to an embodiment of the disclosed subject matter may include semiconductor chips 11 and 12 in an inside thereof. The semiconductor chips 11 and 12 may be electrically connected to substrates 10 by connection terminals 16. Encapsulants 210 covering the semiconductor chips 11 and 12 may be formed on substrates 10.

The connection terminals 16 may include a bonding wire, a beam lead, a conductive tape, or a combination thereof.

FIG. 14 is a cross-sectional view illustrating a preferred configuration of a semiconductor device according to an embodiment of the disclosed subject matter.

Referring to FIG. 14, a semiconductor device 200 according to an embodiment of the disclosed subject matter may include a first semiconductor chip 11 and a second semiconductor chip 12. The first semiconductor chip 11 may be electrically connected to a substrate 10 through flip-chip bonding. An upper surface of the first semiconductor chip 11 may be exposed to be in contact with a first thermoelectric module 50. The second semiconductor chip 12 may be electrically connected to a substrate 10 through wire bonding. An upper surface of the second semiconductor chip 12 may be covered with an encapsulant 210.

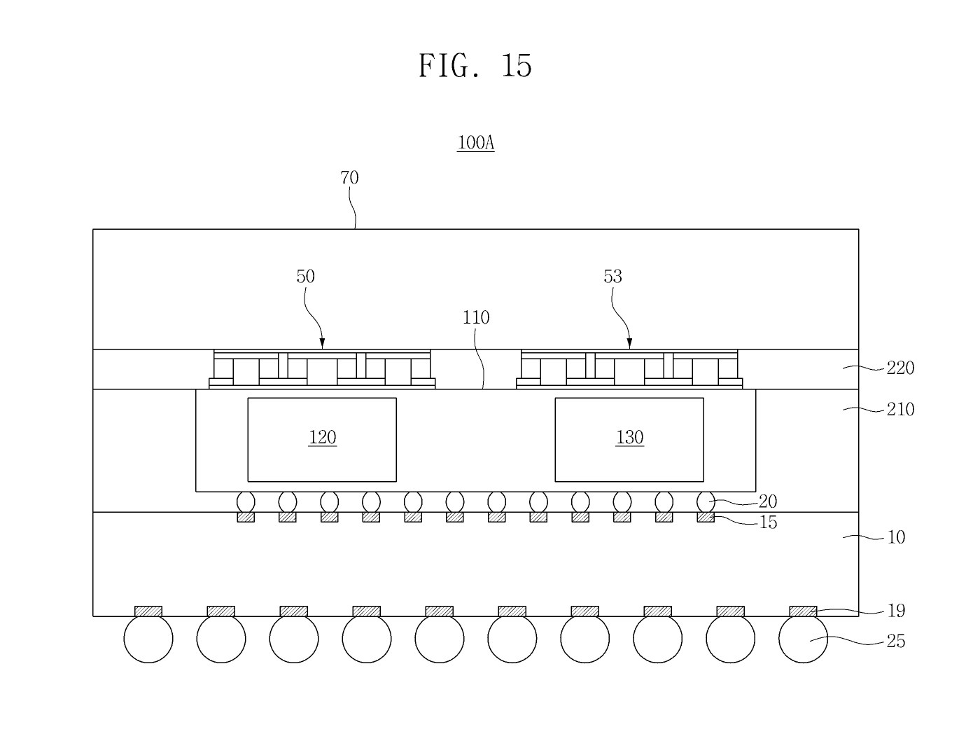

FIG. 15 is a lateral cross-sectional view illustrating a single chip package according to an embodiment of the disclosed subject matter.

Referring to FIG. 15, a single chip package 100A may include a substrate 10, a semiconductor chip 110, first and second thermoelectric modules 50 and 53, and a heat spreader 70. The semiconductor chip 110 may include a high temperature region 120 and a low temperature region 130. The first thermoelectric module 50 may be formed between the heat spreader 70 and the high temperature region 120 of the semiconductor chip 110. The second thermoelectric module 53 may be formed between the heat spreader 70 and the low temperature region 130 of the semiconductor chip 110. The semiconductor chip 110 and an encapsulant 210 may be formed to have the same height. An upper surface of the semiconductor chip 110 may be exposed to be in contact with the first thermoelectric module 50 and the second thermoelectric module 53.

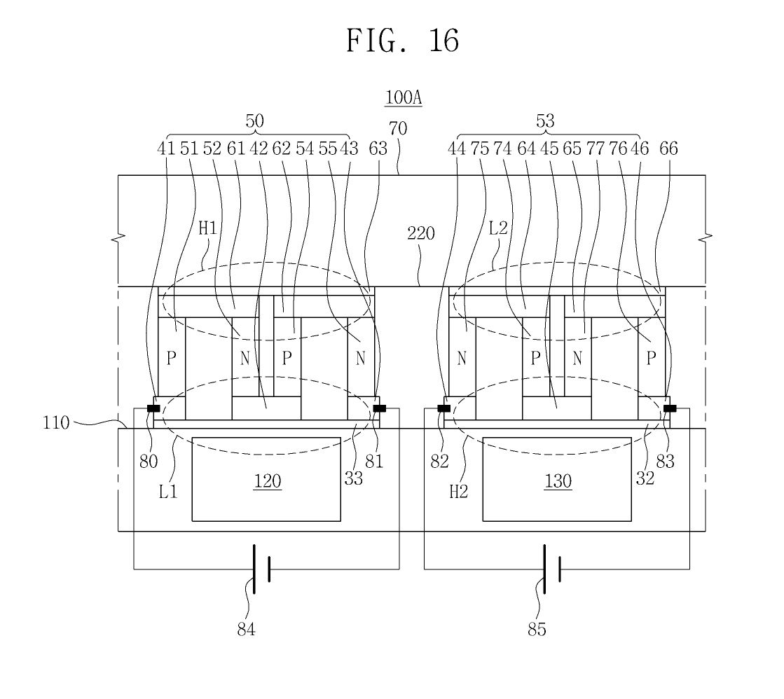

FIG. 16 is a view illustrating a configuration and operation to explain actions of the thermoelectric modules 50 and 53 in a single chip package 100A.

When a first DC power supply 84 is driven to the semiconductor package 100A according to the disclosed subject matter, a first heat absorption portion L1 and a first heat generation portion H1 may be formed.

Referring to FIG. 16, a semiconductor device 200 according to an embodiment of the disclosed subject matter may include a semiconductor chip 110 including a low temperature region 130 and a high temperature region 120. A heat spreader 70 may be formed on the semiconductor chip 110.

The first thermoelectric module 50 having the first heat absorption portion L1 and the first heat generation portion H1 may be included between the high temperature region 120 of the semiconductor chip 110 and the heat spreader 70. The second thermoelectric module 53 having a second heat absorption portion L2 and a second heat generation portion H2 may be included between the low temperature region 130 of the semiconductor chip 110 and the heat spreader 70.

The first heat absorption portion L1 of the first thermoelectric module 50 may be formed close to the high temperature region 120 of the semiconductor chip 110, and the first heat generation portion H1 of the first thermoelectric module 50 may be formed close to the heat spreader 70. The second heat absorption portion L2 of the second thermoelectric module 53 may be formed close to the heat spreader 70 and the second heat generation portion H2 of the second thermoelectric module 53 may be formed close to the low temperature region 130 of the semiconductor chip 110.

The first thermoelectric module 50 may include a second electrode 41, a first P-type thermoelectric semiconductor element 51, a first electrode 61, and a third electrode 42.

The second electrode 41 may be electrically connected to the first P-type thermoelectric semiconductor element 51. The first P-type thermoelectric semiconductor element 51 may be electrically connected to the first electrode 61. The first electrode 61 may be electrically connected to a first N-type thermoelectric semiconductor element 52. The first DC power supply 84 may supply voltages through a positive (+) electrode 80 and a negative (−) electrode 81. The positive (+) electrode 80 may be formed on the second electrode 41, and the negative (−) electrode 81 may be formed on a fifth electrode 43.

A TIM layer 220 may be formed between the heat spreader 70 and the semiconductor chip 110. The TIM layer 220 may be in contact with the heat spreader and the semiconductor chip. For example, the TIM layer 220 may include aluminum oxide (Al₂O₃), zinc oxide (ZnO), a curable resin, or a combination thereof. It is understood that the above are merely a few illustrative examples to which the disclosed subject matter is not limited.

When a second DC power supply 85 is driven to the second thermoelectric module 53 in the semiconductor device 200 of the disclosed subject matter, the second heat absorption portion L2 and the second heat generation portion H2 may be generated. Referring to FIG. 16, the second thermoelectric module 53 may include a seventh electrode 44, a third P-type thermoelectric semiconductor element 74, a sixth electrode 64, a third N-type thermoelectric semiconductor element 75, and an eighth electrode 45.

The seventh electrode 44 may be electrically connected to the third N-type thermoelectric semiconductor element 75. The third N-type thermoelectric semiconductor element 75 may be electrically connected to the sixth electrode 64. The sixth electrode 64 may be electrically connected to the third P-type thermoelectric semiconductor element 74. The second DC power supply 85 may supply voltages through the positive (+) electrode 82 and the negative (−) electrode 83. The positive (+) electrode 82 may be formed on the seventh electrode 44, and the negative (−) electrode 83 may be formed on a tenth electrode 46.

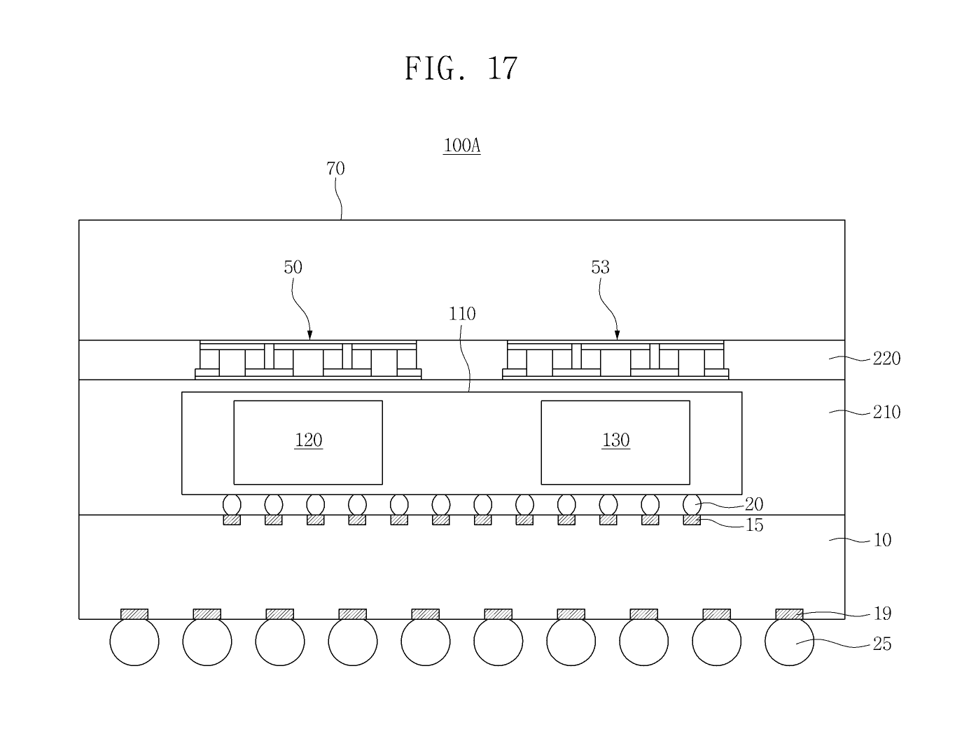

FIGS. 17, 18, and 19 are lateral cross-sectional views illustrating single chip packages according to an embodiment of the disclosed subject matter.

Referring to FIG. 17, a single chip package 100A may include a substrate 10, a semiconductor chip 110, first and second thermoelectric modules 50 and 53, and a heat spreader 70. The semiconductor chip 110 may include a high temperature region 120 and a low temperature region 130. The first thermoelectric module 50 may be formed between the heat spreader 70 and the high temperature region 120 of the semiconductor chip 110. The second thermoelectric module 53 may be formed between the heat spreader 70 and the low temperature region 130 of the semiconductor chip 110. An encapsulant 210 may cover lateral surfaces of the semiconductor chip 110 and bumps 20 and an upper surface of the semiconductor chip 110. A TIM layer 220 may be formed between the encapsulant 210 and the heat spreader 70. The TIM layer 220 may include aluminum oxide (Al₂O₃), zinc oxide (ZnO), a curable resin or epoxy-based resin to which a thermally transferable filler is added, a fluorine resin, or a silicon-based thermal conductive resin. The TIM layer 220 may be omitted.

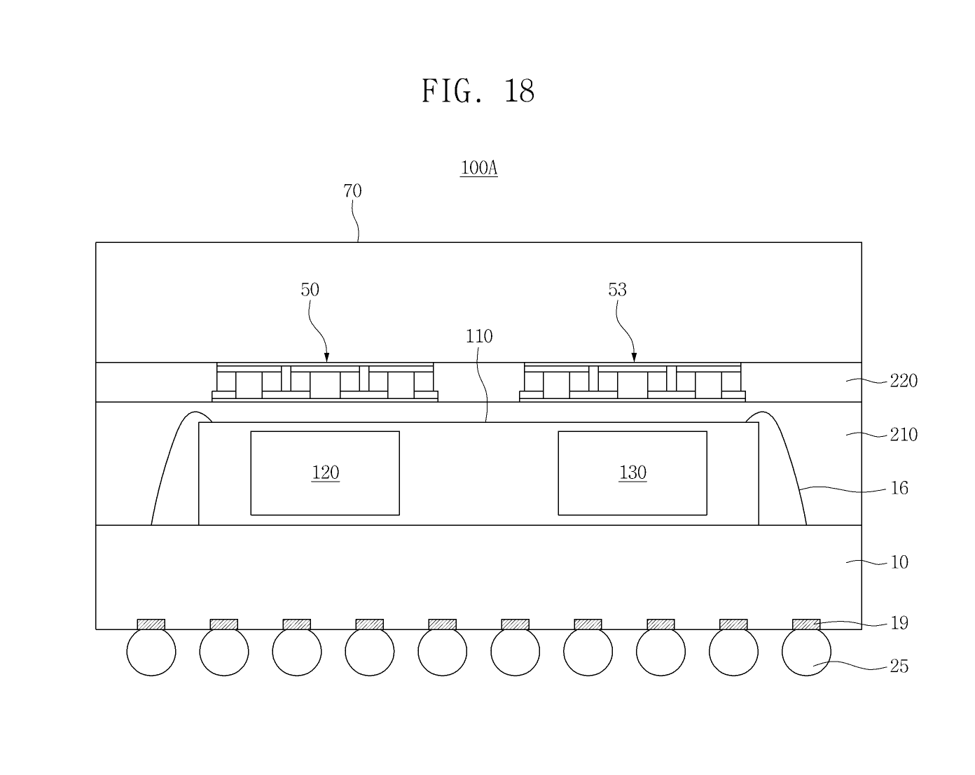

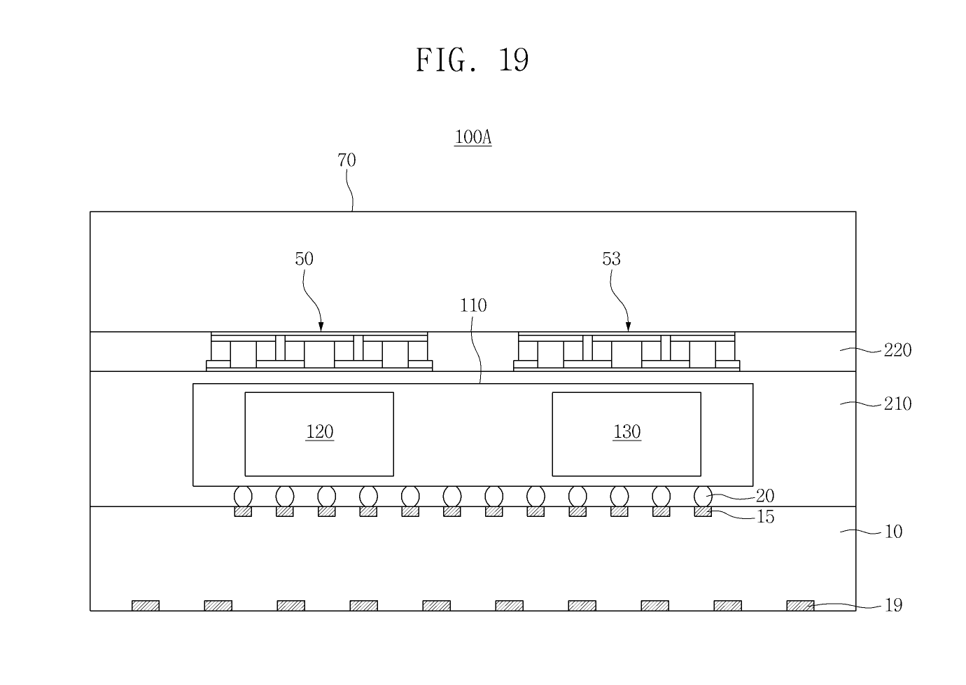

Referring to FIG. 18, a single chip package 100A may include a substrate 10, a semiconductor chip 110, first and second thermoelectric modules 50 and 53, and a heat spreader 70. The semiconductor chip 110 may include a high temperature region 120 and a low temperature region 130. The semiconductor chip 110 may be electrically connected to the substrate 10 by connection terminals 16. An encapsulant 210 covering the semiconductor chip 110 may be formed on the substrate 10.

The connection terminals 16 may include a bonding wire, a beam lead, a conductive tape, or a combination thereof.

Referring to FIG. 19, an external connection member (see 25 of FIG. 1) may be omitted. Lower lands 19 of a semiconductor package 100A may be exposed. The lower lands 19 may include a conductive tab, a finger electrode, a lead grid array (LGA), a pin grid array (PGA), or a combination thereof.

In another embodiment, the lower lands 19 may be omitted.

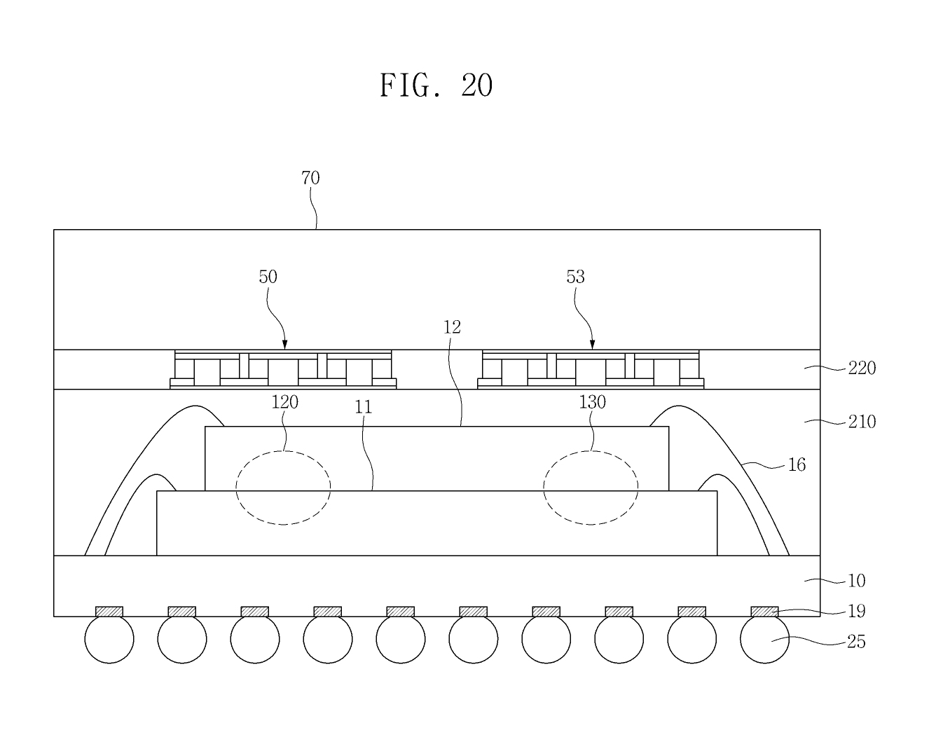

FIGS. 20, 21, and 22 are lateral cross-sectional views illustrating multichip packages according to an embodiment of the disclosed subject matter.

Referring to FIG. 20, a semiconductor package 100 according to an embodiment of the disclosed subject matter may include a first semiconductor chip 11 and a second semiconductor chip 12 mounted on a substrate 10. The second semiconductor chip 12 may be vertically stacked on the first semiconductor chip 11. The first semiconductor chip 11 and the second semiconductor chip 12 may be connected to the substrate 10 through connection terminals 16. An encapsulant 210 covering the first semiconductor chip 11 and the second semiconductor chip 12 may be formed on the substrate 10.

Each of the first semiconductor chip 11 and the second semiconductor chip 12 may be a memory chip such as a volatile memory or a nonvolatile memory. For example, each of the first semiconductor chip 11 and the second semiconductor chip 12 may include a mobile dynamic random access memory (DRAM).

Each of the first semiconductor chip 11 and the second semiconductor chip 12 may include a high temperature region 120 and a low temperature region 130. A first thermoelectric module 50 may be formed between the high temperature region 120 and a heat spreader 70. A second thermoelectric module 53 may be formed between the low temperature region 130 and the heat spreader 70. Configurations and operations of the first thermoelectric module 50 and the second thermoelectric module 53 may be the same as described above.

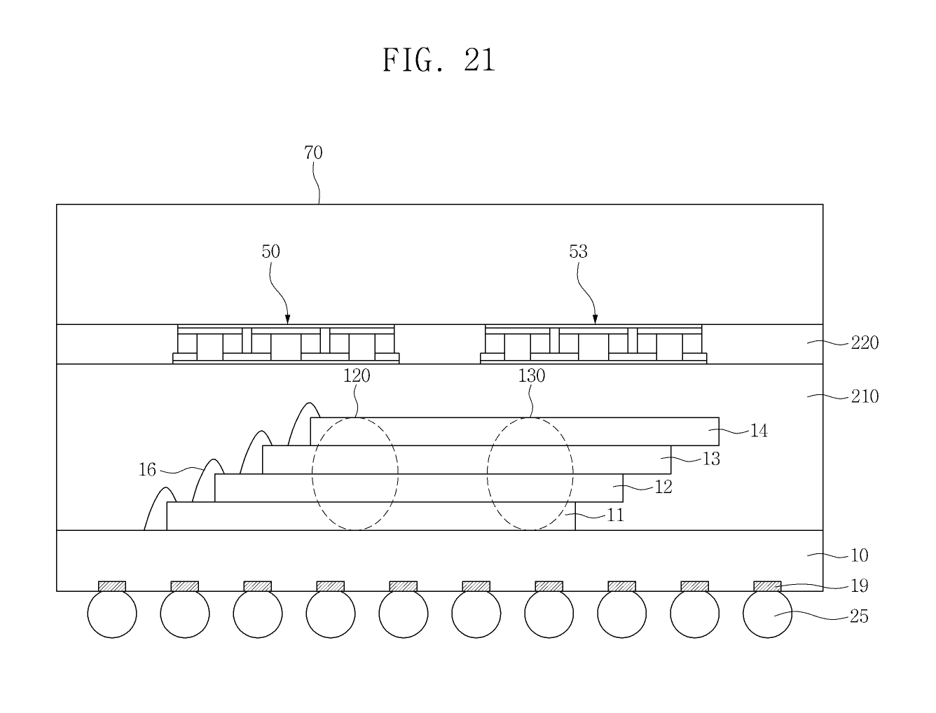

Referring to FIG. 21, a semiconductor package 100 according to an embodiment of the disclosed subject matter may include a first semiconductor chip 11, a second semiconductor chip 12, a third semiconductor chip 13, and a fourth semiconductor chip 14 mounted on a substrate 10. The first to fourth semiconductor chips 11 to 14 may have a cascade stacking structure. The first semiconductor chip 11 and the second semiconductor chip 12 may be electrically connected through a connection terminal 16. The second semiconductor chip 12 and the third semiconductor chip 13 may be electrically connected through a connection terminal 16. The third semiconductor chip 13 and the fourth semiconductor chip 14 may be electrically connected through a connection terminal 16.

A high temperature region 120 may be formed in one sides of the first semiconductor chip 11, the second semiconductor chip 12, the third semiconductor chip 13, and the fourth semiconductor chip 14, and a low temperature region 130 may be formed in the other sides of the first semiconductor chip 11, the second semiconductor chip 12, the third semiconductor chip 13, and the fourth semiconductor chip 14.

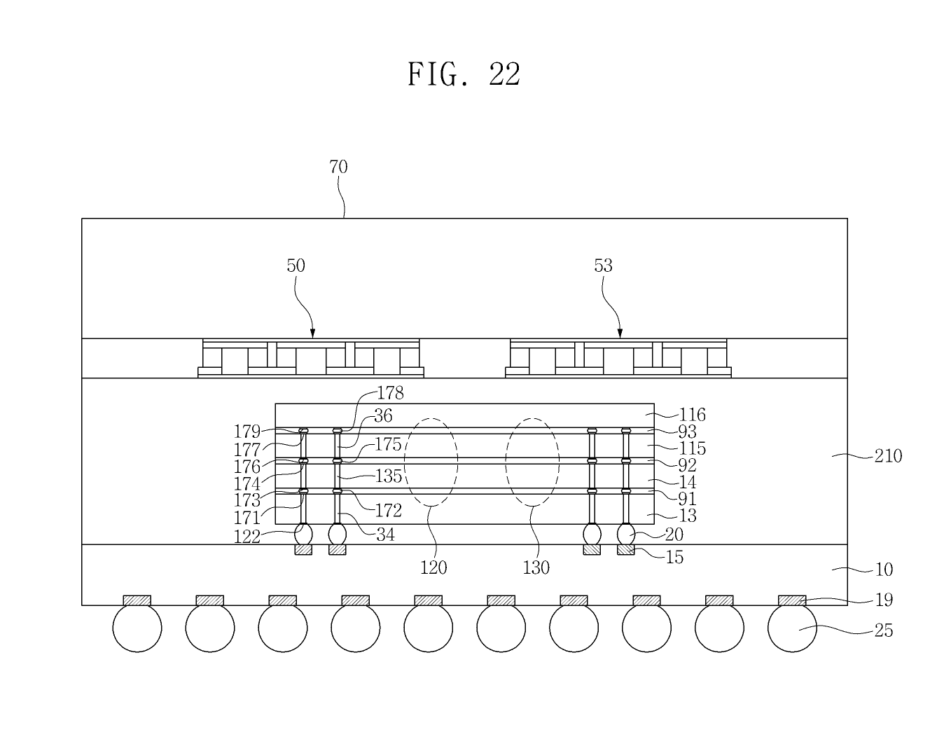

Referring to FIG. 22, third to sixth semiconductor chips 13, 14, 115, and 116 may be sequentially mounted on a substrate 10. Each of the third to sixth semiconductor chips 13, 14, 115, and 116 may be a memory chip such as a volatile memory or a nonvolatile memory.

The third semiconductor chip 13 may include a plurality of third through electrodes 34, a plurality of third lower electrodes 122, and a plurality of third upper electrodes 171. The third through electrodes 34 may pass through the third semiconductor chip 13. The third through electrodes 34 may be formed between the third upper electrodes 171 and the third lower electrodes 122.

The fourth semiconductor chip 14 may include a plurality of fourth through electrodes 135, a plurality of fourth lower electrodes 173, and a plurality of fourth upper electrodes 174. Fourth connection terminals 172 may be formed on the fourth lower electrodes 173. A fourth adhesive layer 91 may be formed between the fourth semiconductor chip 14 and the third semiconductor chip 13. The fourth adhesive layer 91 may be in contact between the fourth semiconductor chip 14 and the third semiconductor chip 13. The fourth connection terminals 172 may be formed between the fourth lower electrodes 173 and the fourth upper electrodes 174. The fourth connection terminals 172 may pass through the fourth adhesive layer 91 to be in contact to the fourth lower electrodes 173 and the third upper electrodes 171.

The fifth semiconductor chip 115 may include a plurality of fifth through electrodes 36, a plurality of fifth lower electrodes 176, and a plurality of fifth upper electrodes 177. Fifth connection terminals 175 may be formed on the fifth lower electrodes 176. A fifth adhesive layer 92 may be formed between the fifth semiconductor chip 115 and the fourth semiconductor chip 14. The fifth adhesive layer 92 may be in contact between the fifth semiconductor chip 115 and the fourth semiconductor chip 14. The fifth connection terminals 175 may be formed between the fifth lower electrodes 176 and the fourth upper electrodes 174. The fifth connection terminals 175 may be formed between the fifth lower electrodes 176 and the fourth upper electrodes 174. The fifth connection terminals 175 may pass through the fifth adhesive layer 92 to be in contact to the fifth lower electrodes 176 and the fourth upper electrodes 174.

The sixth semiconductor chip 116 may include a plurality of sixth lower electrodes 179. Sixth connection terminals 178 may be formed on the sixth lower electrodes 179. A sixth adhesive layer 93 may be formed between the sixth semiconductor chip 116 and the fifth semiconductor chip 115. The sixth adhesive layer 93 may be in contact between the sixth semiconductor chip 116 and the fifth semiconductor chip 115. The fifth upper electrodes 177, the sixth connection terminals 178, and the sixth lower electrodes 179 may penetrate the inside of the sixth adhesive layer 93. The sixth connection terminals 178 may be formed between the sixth lower electrodes 179 and the fifth upper electrodes 177. The sixth connection terminals 178 may pass through the sixth adhesive layer 93 to be in contact to the sixth lower electrodes 179 and the fifth upper electrodes 177.

A horizontal width of the third semiconductor chip 13 may be substantially the same as those of the fourth to sixth semiconductor chips 14, 115, and 116. Lateral surfaces of the fourth to sixth adhesive layers 91, 92, and 93 may be vertically aligned with lateral surfaces of the third to sixth semiconductor chips 13, 14, 115, and 116. An encapsulant 210 covering the third to sixth semiconductor chips 13, 14, 115, and 116 may be formed on the substrate 10. External connection member 25 may be formed on lower lands 19.

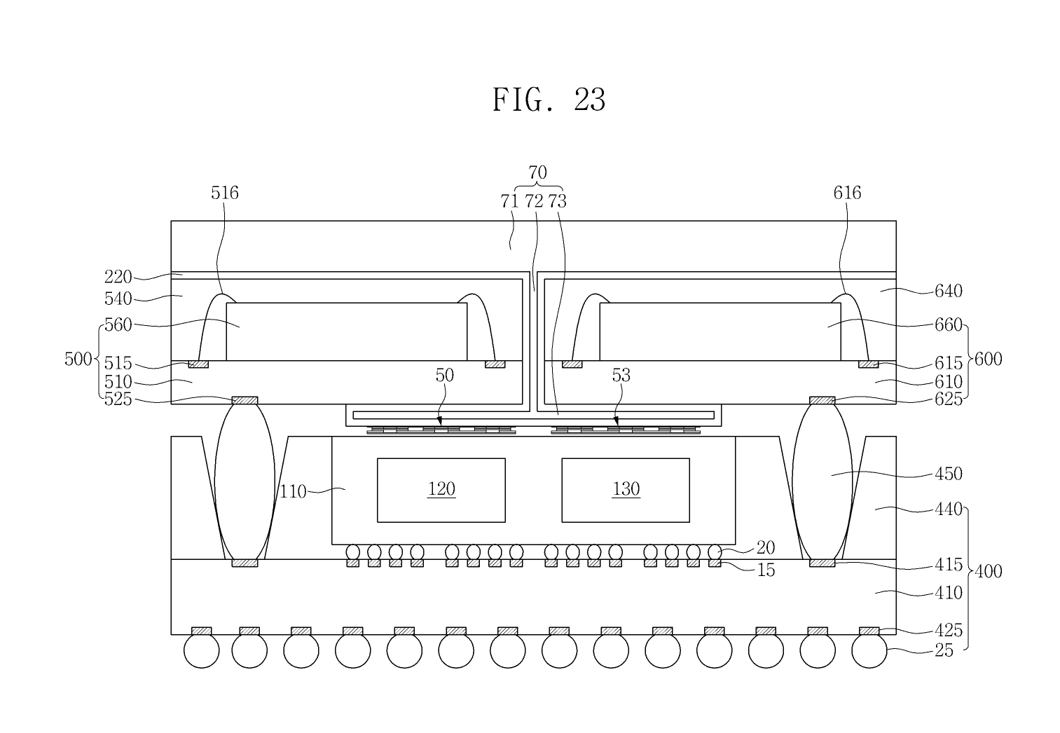

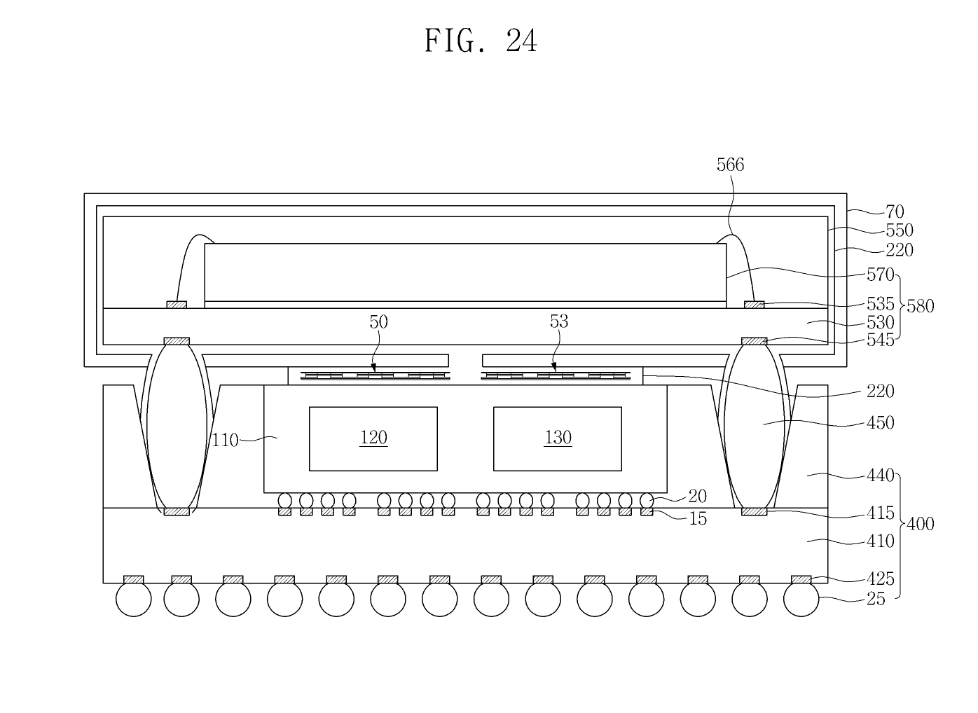

FIGS. 23 and 24 are lateral cross-sectional views illustrating configurations of package-on-packages according to an embodiment of the disclosed subject matter.

Referring to FIG. 23, a first upper package 500, a second upper package 600, and a heat spreader 70 may be mounted on a lower package 400. The heat spreader 70 may include an upper plate 71, a first extension portion 72, and a lower plate 73. The first extension portion 72 may have a vertical height larger than a horizontal width thereof. The first extension portion 72 may have a vertical height larger than the first upper package 500 and the second upper package 600. The lower plate 73 may overlap between the first upper package 500 and the lower package 400, and the lower plate 73 may overlap between the second upper package 600 and the lower package 400. The first extension portion 72 may be connected between the upper plate 71 and the lower plate 73. The heat spreader 70 may be a united body. The upper package 500 may include a first upper encapsulant 540. The second upper package 600 may include a second upper encapsulant 640. The first upper package 500 may include a first upper connection terminal 516. The second upper package 600 may include a second upper connection terminal 616.

The first upper package 500 may include a first upper semiconductor chip 560 mounted on a first upper substrate 510. The second upper package 600 may include a second upper semiconductor chip 660 mounted on the second upper substrate 610.

The first upper substrate 510 may include a first upper land 515 and the second upper land 525. The second upper substrate 610 may include a third upper land 615 and a fourth upper land 625.

Each of the first upper semiconductor chip 560 and the second upper semiconductor chip 660 may be a memory chip such as a volatile memory or a nonvolatile memory. For example, each of the first upper semiconductor chip 560 and the second upper semiconductor chip 660 may include a mobile DRAM.

The lower package 400 may include a semiconductor chip 110 mounted on a first substrate 410. The semiconductor chip 110 may be mounted on the first substrate 410 through a flip-chip bonding method. The semiconductor chip 110 may be electrically connected onto a bump land 15 via a bump 20.

An inter-package connection unit 450 may be formed between the first upper substrate 510 and the first substrate 410. An inter-package connection unit 450 may be formed between the second upper substrate 610 and the first substrate 410. The inter-package connection unit 450 may electrically connect the second upper land 525 and a first lower land 415. The inter-package connection unit 450 may electrically connect the fourth upper land 625 and a first lower land 415.

The semiconductor chip 110 may include a high temperature region 120 and a low temperature region 130. The semiconductor chip 110 may be formed to have the same height as a lower encapsulant 440.

A first thermoelectric module 50 may be formed between the high temperature region 120 and the heat spreader 70. A second thermoelectric module 53 may be formed between the low temperature region 130 and the heat spreader 70. A TIM layer 220 may be formed between the heat spreader 70 and the first thermoelectric module 50 and between the heat spreader 70 and the second thermoelectric module 53. The heat exchange between the first and second thermoelectric modules 50 and 53 may be the same as described above.

The TIM layer 220 may be formed between the first upper package 500 and the lower package 400. The TIM layer 220 may be formed between the second upper package 600 and the lower package 400. The TIM layer 220 may be omitted.

The configurations and operations of the first thermoelectric module 50 and the second thermoelectric module 53 may be the same as described above.

Referring to FIG. 24, an upper package 580 and a heat spreader 70 may be formed on the lower package 400. The upper package 580 may be surrounded with the heat spreader 70. A TIM layer 220 may be formed between the upper package 580 and a lower encapsulant 440. The upper package 580 may include an upper encapsulant 550. The upper package 580 may include an upper connection terminal 566.

The upper package 580 may include an upper semiconductor chip 570 mounted on an upper substrate 530. The upper substrate 530 may include a fifth upper land 535 and a sixth upper land 545.

The upper semiconductor chip 570 may include a memory chip such as a volatile memory or a nonvolatile memory. For example, the upper semiconductor chip 570 may include a mobile DRAM.

An inter-package connection unit 450 may be formed between the upper substrate 530 and the first substrate 410. The inter-package connection unit 450 may electrically connect the sixth upper land 545 and a first lower land 415.

A first thermoelectric module 50 and a second thermoelectric module 53 may be formed between the upper package 580 and the lower package 400.

The lower package 400 may include a semiconductor chip 110. The semiconductor chip 110 may include a high temperature region 120 and a low temperature region 130. The semiconductor chip 110 may be electrically connected to the lower substrate 410 via a bump 20.

The first thermoelectric module 50 may be formed between the high temperature region 120 and the heat spreader 70. The second thermoelectric module 53 may be formed between the low temperature region 130 and the heat spreader 70. A TIM layer 220 may be formed between the heat spreader 70 and the first thermoelectric module 50 and between the heat spreader 70 and the second thermoelectric module 53. The heat exchange between the first and second thermoelectric modules 50 and 53 may be the same as described above.

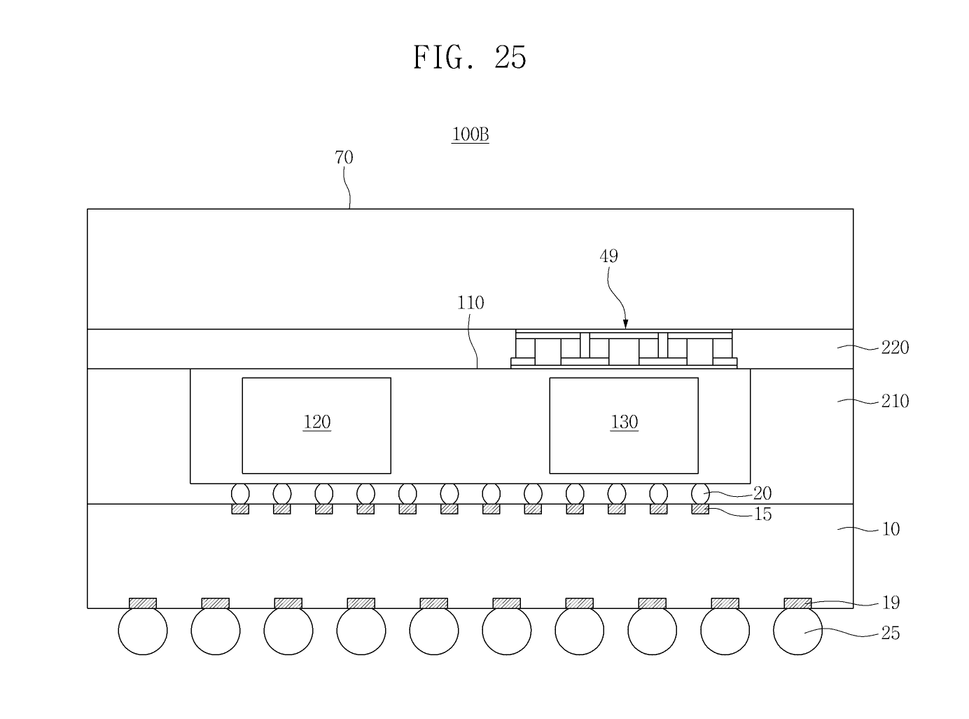

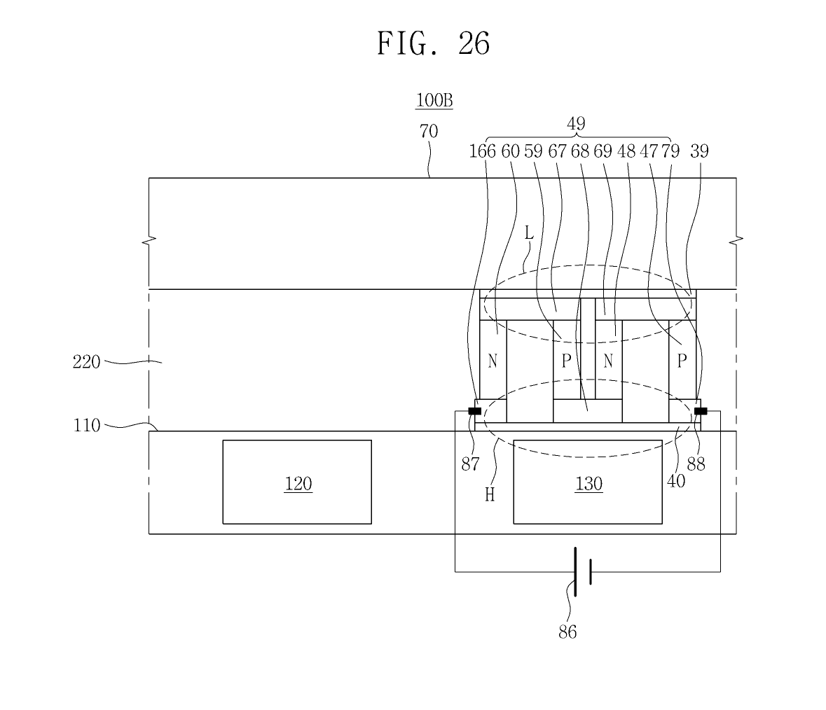

FIGS. 25 and 26 are views illustrating a single chip package, and a cooling operation using one thermoelectric module of components of the single chip package.

Referring to FIG. 25, a single chip package 100B may include a substrate 10, a semiconductor chip 110, a thermoelectric module 49, and a heat spreader 70. The semiconductor chip 110 may include a high temperature region 120 and a low temperature region 130. A TIM layer 220 may be formed between the heat spreader 70 and the high temperature region of the semiconductor chip 110. The thermoelectric module 49 may be formed between the heat spreader 70 and the low temperature region 130 of the semiconductor chip 110. The semiconductor package 110 and an encapsulant 210 may be formed to have the same height. An upper surface of the semiconductor chip 110 may be exposed to be in contact with the TIM layer 220 and the thermoelectric module 49.

FIG. 26 is a view illustrating a configuration and operation of a thermoelectric module 49 in a single semiconductor package 100B according to another embodiment of the disclosed subject matter.

When a DC power supply 86 is driven to the semiconductor package 100B of the disclosed subject matter, a heat absorption portion L and a heat generation portion H may be generated. Referring to FIG. 26, the thermoelectric module 49 may include a twelfth electrode 166, a fifth P-type thermoelectric semiconductor element 59, a fifth N-type thermoelectric semiconductor element 60, an eleventh electrode 67, and a thirteenth electrode 68.

The twelfth electrode 166 may be electrically connected to the fifth N-type thermoelectric semiconductor element 60. The fifth N-type thermoelectric semiconductor element 60 may be electrically connected to the eleventh electrode 67. The eleventh electrode 67 may be electrically connected to the fifth P-type thermoelectric semiconductor element 59. A DC power supply 86 may supply voltages through a positive (+) electrode 87 and a negative (−) electrode 88. The positive (+) electrode 87 may be formed on the twelfth electrode 166, and the negative (−) electrode 88 may be formed on a fifteenth electrode 79. A sixth N-type thermoelectric semiconductor element 48 and a sixth P-type thermoelectric semiconductor element 47 may be in a state to be connected to a fourteenth electrode 69.

A sixth insulating layer 40 may be formed between the twelfth electrode 166 and the semiconductor chip 110 and between the fifteenth electrode 79 and the semiconductor chip 110. A fifth insulating layer 39 may be formed between the eleventh electrode 67 and a heat spreader 70 and between the fourteenth electrode 69 and the heat spreader 70. The sixth insulating layer 40 may emit heat absorbed from the heat spreader 70 in the fifth insulating layer 39 toward the low temperature region 130 of the semiconductor chip 110. The fifth insulating layer 39 and the sixth insulating layer 40 may include a thermally transferable material. For example, an epoxy-based resin to which a thermally transferable filler is added, a fluorine resin, or a silicon-based thermal conductive resin may be used as the fifth and sixth insulating layers 39 and 40.

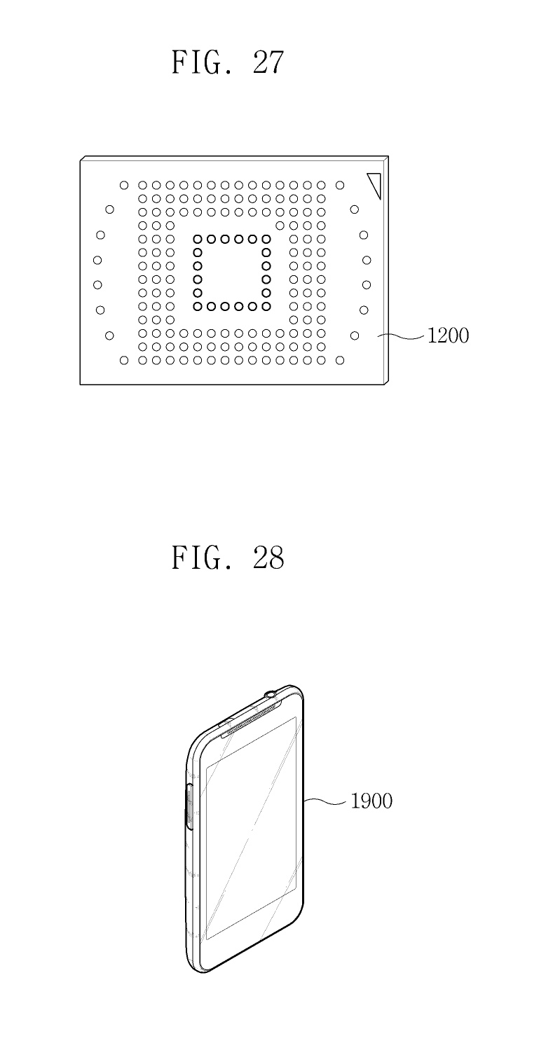

FIGS. 27, 28, and 29 are perspective views and block diagrams of electronic apparatuses according to embodiments of the disclosed subject matter.

Referring to FIGS. 27, 28, and 29, the semiconductor devices described with reference to FIGS. 1 to 24 may be usefully applied to an electronic system such as an embedded multi-media chip 1200 of FIG. 27, a smart phone 1900 of FIG. 28, a netbook, a notebook, or a tablet PC. For example, a semiconductor device similar to the semiconductor devices as described with FIGS. 1 to 24 may be mounted on a main board in the smart phone 1900 of FIG. 28.

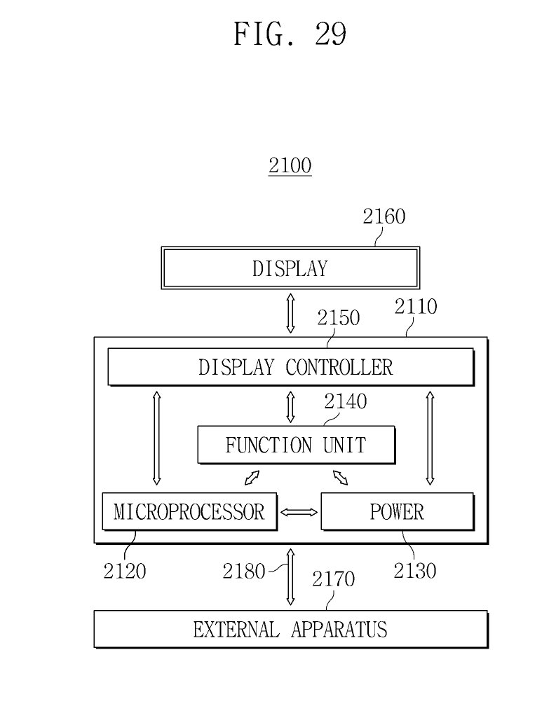

Referring to FIG. 29, a semiconductor device similar to the semiconductor devices as described with FIGS. 1 to 24 may be applied to an electronic system 2100. The electronic system may include a body 2110, a microprocessor (MP) unit 2120, a power unit 2130, a function unit 2140, and a display controller unit 2150. The body 2110 may be a mother board formed of a PCB. The MP unit 2120, the power unit 2130, the function unit 2140, and the display controller unit 2150 may be mounted on the body 2110. A display unit 2160 may be disposed inside the body 2110 or outside the body 2110. For example, the display unit 2160 may be disposed on a surface of the body 2110 and display an image processed by the display controller unit 2150.

The power unit 2130 may receive a predetermined voltage from an external power source, divide the predetermined voltage into various voltage levels, and transmit divided voltages to the MP unit 2120, the function unit 2140, and the display controller unit 2150. The MP unit 2120 may receive a voltage from the power unit 2130 and control the function unit 2140 and the display unit 2160. The function unit 2140 may perform various functions of the electronic system 2100. For instance, when the electronic system 2100 is a smart phone, the function unit 2140 may include several components capable of performing portable phone functions, such as output of an image to the display unit 2160 or output of a voice to a speaker, by dialing or communication with an external apparatus 2170. When the function unit 2140 includes a camera, the function unit 2140 may serve as a camera image processor.

In applied embodiments, when the electronic system 2100 is connected to a memory card to increase capacity, the function unit 2140 may be a memory card controller. The function unit 2140 may exchange signals with the external apparatus 2170 through a wired or wireless communication unit 2180. In addition, when the electronic system 2100 needs a universal serial bus (USB) to expand functions thereof, the function unit 2140 may serve as an interface controller. The function unit 2140 may include a large capacity data storage device.

A semiconductor device similar to the semiconductor devices described with reference to FIGS. 1 to 24 may be applied to the function unit 2140.

According to the semiconductor devices having a thermoelectric module according to various embodiments of the disclosed subject matter, a semiconductor device which can use as many semiconductor packages as possible by combining a plurality of thermoelectric modules to have opposite polarities may be provided.

The semiconductor devices according to various embodiments of the disclosed subject matter include an active control mechanism configured to convert heat generated in a semiconductor package into electrical energy, and convert the electrical energy absorbed in the thermoelectric module into heat energy in a heat spreader to improve temperature uniformity of the semiconductor package and cooling efficiency of the semiconductor package.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this disclosed subject matter as defined in the claims. In the claims, means-plus-function clauses are intended to cover the structures described herein as performing the recited function, and not only structural equivalents but also equivalent structures.

What is claimed is:

1. A semiconductor device, comprising:
a first semiconductor package;
a second semiconductor package adjacent to the first semiconductor package;
a heat spreader formed on the first and second semiconductor packages;
a first thermoelectric module between the first semiconductor package and the heat spreader;
a second thermoelectric module between the second semiconductor package and the heat spreader;
a first temperature sensor between the first thermoelectric module and the first semiconductor package;
a second temperature sensor between the first thermoelectric module and the heat spreader; and
a controller electrically connected to the first and second temperature sensors.

2. The semiconductor device of claim 1, wherein the first thermoelectric module includes:
a first thermoelectric pair having a first P-type thermoelectric semiconductor element, and a first N-type thermoelectric semiconductor element spaced apart from the first P-type thermoelectric semiconductor element;
a first electrode connected to the first P-type thermoelectric semiconductor element and the first N-type thermoelectric semiconductor element and disposed between the first thermoelectric pair and the heat spreader;
a second electrode connected to the first P-type thermoelectric semiconductor element and disposed between the first thermoelectric pair and the first semiconductor package; and
a third electrode connected to the first N-type thermoelectric semiconductor element and disposed between the first thermoelectric pair and the first semiconductor package,
wherein voltages are applied through the second electrode connected to the first P-type thermoelectric semiconductor element and the third electrode connected to the first N-type thermoelectric semiconductor element.

3. The semiconductor device of claim 2, wherein when a temperature measured by the first temperature sensor is equal to or larger than a first target temperature, a positive bias is applied to the second electrode connected to the first P-type thermoelectric semiconductor element, and a negative bias is applied to the third electrode connected to the first N-type thermoelectric semiconductor element.

4. The semiconductor device of claim 2, wherein when the temperature measured in the first temperature sensor is less than a first target temperature, the voltages applied to the second electrode connected to the first P-type thermoelectric semiconductor element and the third electrode connected to the first N-type thermoelectric semiconductor element are removed.

5. The semiconductor device of claim 2, further comprising a thermal interface material layer disposed between the first electrode and the first semiconductor package.

6. The semiconductor device of claim 1, wherein the first thermoelectric module includes:
a first thermoelectric pair having a first P-type thermoelectric semiconductor element, and a first N-type thermoelectric semiconductor element spaced apart from the first P-type thermoelectric semiconductor element;
a second thermoelectric pair having a second P-type thermoelectric semiconductor element, and a second N-type thermoelectric semiconductor element spaced apart from the second P-type thermoelectric semiconductor element;
a first electrode connected to the first P-type thermoelectric semiconductor element and the first N-type thermoelectric semiconductor element and disposed between the first thermoelectric pair and the heat spreader;
a second electrode connected to the first P-type thermoelectric semiconductor element and disposed between the first thermoelectric pair and the first semiconductor package;
a third electrode connected to the first N-type thermoelectric semiconductor element and the second P-type thermoelectric semiconductor element and disposed between the first N-type thermoelectric semiconductor element and the first semiconductor package and between the second P-type thermoelectric semiconductor element and the first semiconductor package;
a fourth electrode connected to the second P-type thermoelectric semiconductor element and the second N-type thermoelectric semiconductor element and disposed between the second thermoelectric pair and the heat spreader; and
a fifth electrode connected to the second N-type thermoelectric semiconductor element and disposed between the second thermoelectric pair and the first semiconductor package,
wherein voltages are applied through the second electrode connected to the first P-type thermoelectric semiconductor element and the fifth electrode connected to the second N-type thermoelectric semiconductor element.

7. The semiconductor device of claim 1, wherein the second thermoelectric module includes:
a third thermoelectric pair including a third P-type thermoelectric semiconductor element, and a third N-type thermoelectric semiconductor element spaced apart from the third P-type thermoelectric semiconductor element;
a sixth electrode connected to the third P-type thermoelectric semiconductor element and the third N-type thermoelectric semiconductor element and disposed between the third thermoelectric pair and the heat spreader;
a seventh electrode connected to the third N-type thermoelectric semiconductor element and disposed between the third thermoelectric pair and the second semiconductor package; and
an eighth electrode connected to the third P-type thermoelectric semiconductor element and disposed between the third thermoelectric pair and the second semiconductor package,
wherein voltages are applied through the seventh electrode connected to the third N-type thermoelectric semiconductor element and the eighth electrode connected to the third P-type thermoelectric semiconductor element.

8. The semiconductor device of claim 7, wherein when a temperature measured by the second temperature sensor is equal to or larger than a second target temperature, a positive bias is applied to the seventh electrode connected to the third N-type thermoelectric semiconductor element, and a negative bias is applied to the eighth electrode connected to the third P-type thermoelectric semiconductor element.

9. The semiconductor device of claim 7, wherein when a temperature measured by the second temperature sensor is less than a second target temperature, a negative bias is applied to the seventh electrode connected to the third N-type thermoelectric semiconductor element, and the eighth electrode connected to the third P-type thermoelectric semiconductor element.

10. The semiconductor device of claim 7, further comprising a third temperature sensor disposed between the second thermoelectric module and the second semiconductor package,
wherein when a temperature measured by the third temperature sensor is equal to or larger than a first target temperature, a negative bias is applied to the seventh electrode connected to the third N-type thermoelectric semiconductor element, and a positive bias is applied to the eighth electrode connected to the third P-type thermoelectric semiconductor element.

11. The semiconductor device of claim 7, further comprising a third temperature sensor disposed between the second thermoelectric module and the second semiconductor package,
wherein when a temperature measured by the third temperature sensor is equal to or larger than a first target temperature, the voltages applied to the seventh electrode connected to the third N-type thermoelectric semiconductor element and the eighth electrode connected to the third P-type thermoelectric semiconductor element are removed.

12. The semiconductor device of claim 7, wherein the second thermoelectric module includes:
a third thermoelectric pair including a third N-type thermoelectric semiconductor element, and a third P-type thermoelectric semiconductor element spaced apart from the third N-type thermoelectric semiconductor element;
a fourth thermoelectric pair including a fourth N-type thermoelectric semiconductor element, and a fourth P-type thermoelectric semiconductor element spaced apart from the fourth N-type thermoelectric semiconductor element;
a sixth electrode connected to the third N-type thermoelectric semiconductor element and the third P-type thermoelectric semiconductor element and disposed between the third thermoelectric pair and the heat spreader;
a seventh electrode connected to the third N-type thermoelectric semiconductor element and disposed between the third thermoelectric pair and the second semiconductor package;
an eighth electrode connected to the third P-type thermoelectric semiconductor element and the fourth N-type thermoelectric semiconductor element and disposed between the third P-type thermoelectric semiconductor element and the second semiconductor package and between the fourth N-type thermoelectric semiconductor element and the second semiconductor package;
a ninth electrode connected to the fourth N-type thermoelectric semiconductor element and the fourth P-type thermoelectric semiconductor element and disposed between the fourth thermoelectric pair and the heat spreader; and
a tenth electrode connected to the fourth P-type thermoelectric semiconductor element and disposed between the fourth thermoelectric pair and the second semiconductor package,
wherein voltages are applied through the seventh electrode connected to the third N-type thermoelectric semiconductor element and the tenth electrode connected to the fourth P-type thermoelectric semiconductor element.

13. The semiconductor device of claim 1, wherein the heat spreader includes one of copper (Cu), silver (Ag), gold (Au), platinum (Pt), tin (Sn), aluminum (Al), and an alloy thereof.

14. The semiconductor device of claim 1, wherein the first temperature sensor includes a thermocouple.

15. A semiconductor device, comprising:
a semiconductor chip having a low temperature region and a high temperature region;
a heat spreader formed on the semiconductor chip;
a first thermoelectric module having a first heat absorption portion and a first heat generation portion, and disposed between the high temperature region of the semiconductor chip and the heat spreader; and
a second thermoelectric module having a second heat absorption portion and a second heat generation portion, and disposed between the low temperature region of the semiconductor chip and the heat spreader,
wherein the first heat absorption portion of the first thermoelectric module is close to the high temperature region of the semiconductor chip, and the first heat generation portion of the first thermoelectric module is close to the heat spreader, and
the second heat absorption portion of the second thermoelectric module is close to the heat spreader, and the second heat generation portion of the second thermoelectric module is close to the low temperature region of the semiconductor chip.

16. An apparatus comprising:
a semiconductor device;
a heat spreader;
a plurality of thermoelectric modules disposed between the semiconductor device and the heat spreader, and each thermoelectric module configured to either absorb heat or generate heat in response to a respective applied voltage; and
a controller configured to apply a respective voltage to each of the thermoelectric modules in order to pump heat between the semiconductor device and the heat spreader.

17. The apparatus of claim 16, wherein the controller is configured to:
cause a first portion of the thermoelectric modules to absorb heat, and
cause a second portion of the thermoelectric modules to generate heat.

18. The apparatus of claim 16, further comprising:
a first temperature sensor disposed to measure a first temperature of the semiconductor device, and
a second temperature sensor disposed to measure a second temperature of the heat spreader; and
wherein the controller is configured to select, for each thermoelectric module, a respective voltage based, at least in part, upon the first temperature and the second temperature.

19. The apparatus of claim 16, wherein the controller is configured to cause the plurality of thermoelectric modules to absorb heat at a first location, and generate a substantially equivalent amount of heat at a second location.

20. The apparatus of claim 16, wherein the semiconductor device includes a plurality of semiconductor packages; and
wherein the controller is configured to apply a respective voltage to each of the thermoelectric modules in order to reduce a temperature difference between the plurality of semiconductor packages.
